(19) United States
(12) Patent Application Publication
(10) Pub. No.: US 2025/0309396 A1
(43) Pub. Date: Oct. 2, 2025

(54) POWER STORAGE MODULE

(71) Applicant: SEMICONDUCTOR ENERGY LABORATORY CO., LTD., Atsugi-shi, Kanagawa-ken (JP)

(72) Inventors: Takeshi OSADA, Isehara, Kanagawa (JP); Haruki KATAGIRI, Atsugi, Kanagawa (JP); Yosuke TSUKAMOTO, Atsugi, Kanagawa (JP)

(21) Appl. No.: 18/863,737

(22) PCT Filed: May 1, 2023
(86) PCT No.: PCT/IB2023/054507

§ 371 Date: Nov. 7, 2024

(30) Foreign Application Priority Data
May 19, 2022 (JP) 2022-082390

(51) Int. Cl. H01M 10/633; B60L 58/27; H01M 10/48; H01M 10/615; H01M 10/625; H01M 10/643; H01M 10/647; H01M 10/6571; H01M 50/209; H01M 50/213; H01M 50/51

(52) U.S. Cl. CPC H01M 10/633; H01M 10/482; H01M 10/486; H01M 10/615; H01M 10/625; H01M 10/643; H01M 10/647; H01M 10/6571; H01M 50/209; H01M 50/213; H01M 50/51; B60L 58/27; B60L 2200/10; B60L 2200/12; B60L 2200/18; B60L 2200/26; H01M 2220/20

(57) ABSTRACT

A power storage module which includes a plurality of batteries connected in series and is capable of controlling operation of a heater on the basis of a battery with the lowest battery temperature is provided. The power storage module includes a first battery and a second battery connected in series, the heater, and a control circuit; the heater is provided close to the first battery and the second battery and is electrically connected to an IC included in the control circuit; the control circuit includes a first voltage sensor that senses a voltage of the first battery, a second voltage sensor that senses a voltage of the second battery, and a current sensor that senses a current flowing through the first battery and the second battery; and in charging the first battery and the second battery, the heater is turned on by a signal from the IC in the case where a differential voltage between a first peak voltage of dQ/dV calculated from a detection value of each of the first voltage sensor and the current sensor and a second peak voltage of dQ/dV calculated from a detection value of each of the second voltage sensor and the current sensor is higher than or equal to 5 mV.

### TECHNICAL FIELD

The invention disclosed in this specification and the like (hereinafter sometimes referred to as “the present invention” in this specification and the like) relates to a power storage device, a secondary battery, and the like. In particular, the present invention relates to a lithium-ion battery.

The present invention relates to an object, a method, or a manufacturing method. Alternatively, the present invention relates to a process, a machine, manufacture, or a composition (composition of matter). Alternatively, the present invention relates to a semiconductor device, a display device, a light-emitting device, a power storage device, a lighting device, an electronic device, a vehicle, or a manufacturing method thereof.

### BACKGROUND ART

In recent years, a variety of power storage devices such as lithium-ion batteries, lithium ion capacitors, and air batteries have been actively developed. In particular, demands for lithium-ion batteries with high output and high energy density have rapidly grown with the development of the semiconductor industry, for portable information terminals such as mobile phones, smartphones, and laptop computers, portable music players, digital cameras, medical equipment, electric motor vehicles such as hybrid electric vehicles (HVs), electric vehicles (EVs), and plug-in hybrid electric vehicles (PHVs), and the like, and the lithium-ion batteries are essential as rechargeable energy supply sources for today's information society.

In a power storage device (sometimes referred to as a battery, a secondary battery, or the like), charge characteristics and/or discharge characteristics change depending on a charge environment and/or a discharge environment of the battery. For example, it is known that the discharge capacity of a lithium-ion battery becomes small in a low-temperature environment, i.e., when the temperature of the battery is low.

Hence, a power storage unit is proposed that can heat a battery with a heater provided adjacent to the battery in the case where a power storage device (sometimes referred to as a battery, a secondary battery, or the like) is in a low-temperature environment (e.g., see Patent Document 1).

### REFERENCE

### Patent Document

[Patent Document 1] Japanese Published Patent Application No. 2014-30340

### SUMMARY OF THE INVENTION

### Problems to be Solved by the Invention

Patent Document 1 discloses a structure in which a heater is provided adjacent to a battery. Here, when a structure in which a power storage module including a plurality of batteries is heated by one heater is considered, it is probable that the temperatures of the batteries in the module might be different from each other depending on the location where the batteries are provided. In such a case, when a battery with a low temperature is included in the plurality of batteries, degradation of the battery capacity of the battery with a low temperature might accelerate. In addition, the risk of lithium being deposited on a negative electrode due to the low temperature might increase.

As the temperature control in such a case, it is desirable that the heater be operated on the basis of a battery with the lowest temperature among the plurality of batteries included in the power storage module.

When the temperatures of the plurality of batteries are different from each other, a conceivable structure is such that a temperature sensor (a thermistor, a thermocouple, or the like) is provided for each of the plurality of batteries and the temperature sensor is connected to a control circuit of the power storage module to control the temperature. However, since the manufacturing cost is increased when each of the plurality of batteries is provided with a temperature sensor, a small number of commercially available power storage modules including a temperature sensor for each battery is observed.

Note that in the case where a plurality of stages of batteries are connected in series in the power storage module including a plurality of batteries, a plurality of voltage sensors are included to sense a voltage of each of the stages that are connected in series. This is because prevention of overcharge in a lithium-ion battery is one of the important requirements in terms of safety, and only sensing the total voltage of the plurality of batteries connected in series cannot sense overcharge when any of the stages of batteries connected in series is overcharged. A power storage module with such a structure includes at least one current sensor in most cases.

An object of one embodiment of the present invention is to achieve low-cost control for operating a heater on the basis of a battery with the lowest battery temperature in a power storage module including a plurality of batteries. Specifically, an object is to achieve control for operating a heater on the basis of a battery with the lowest battery temperature by using voltage sensors and a current sensor included in a power storage module. Another object is to provide a power storage module that can control operation of a heater on the basis of a battery with the lowest battery temperature by using voltage sensors and a current sensor connected to a plurality of batteries connected in series.

Note that the description of these objects does not preclude the existence of other objects. One embodiment of the present invention does not need to achieve all these objects. Other objects can be derived from the descriptions of the specification, the drawings, the claims, and the like.

### Means for Solving the Problems

When a variation in the temperatures of the plurality of batteries included in the power storage module can be found with use of the structure of the power storage module of one embodiment of the present invention from voltage values and a current value sensed by the above-described voltage sensors and current sensor without using a temperature sensor, there is a possibility that a temperature sensor does not need to be provided for each of the plurality of batteries to perform favorable temperature control in the power storage module. That is, in the power storage module including the plurality of batteries, even when the number of temperature sensors is smaller than the number of batteries, favorable temperature control can be performed in the power storage module, whereby a reduction in cost of the power storage module can be achieved.

One embodiment of the present invention is a power storage module including a first battery, a second battery, a heater, and a control circuit; the first battery and the second battery are connected in series; the heater is provided close to the first battery and the second battery; the heater is electrically connected to an IC included in the control circuit; the control circuit includes a first voltage sensor that senses a voltage of the first battery, a second voltage sensor that senses a voltage of the second battery, and a current sensor that senses a current flowing through the first battery and the second battery; and in charging the first battery and the second battery, the heater is turned on by a signal from the IC in the case where a differential voltage between a first peak voltage of dQ/dV calculated from a detection value of each of the first voltage sensor and the current sensor and a second peak voltage of dQ/dV calculated from a detection value of each of the second voltage sensor and the current sensor is higher than or equal to 5 mV.

In the above, it is preferable that the power storage module include a temperature sensor, the temperature sensor be electrically connected to the IC, the temperature sensor be provided close to the first battery or the second battery, and after the heater is turned on, the heater be turned off by a signal from the IC in the case where a detection temperature of the temperature sensor is higher than or equal to 25° C.

Alternatively, in the above, it is preferable that the power storage module include a temperature sensor, the temperature sensor be electrically connected to the IC, the temperature sensor be provided close to the first battery or the second battery, and in the case where the heater is turned on by the signal from the IC, a first detection temperature be a detection temperature of the temperature sensor immediately before the heater is turned on and the heater be turned off by a signal from the IC when a detection temperature of the temperature sensor is a temperature that is 5° C. higher than the first detection temperature.

Alternatively, in the above, it is preferable that after the heater is turned on, the heater be turned off by a signal from the IC in the case where a certain period of time elapses.

In the power storage module including the temperature sensor described in any of the above, it is preferable that in charging the first battery and the second battery, the heater be turned on by the signal from the IC in the case where the detection temperature of the temperature sensor is lower than 10° C. and the heater be turned off by the signal from the IC when the detection temperature of the temperature sensor is higher than or equal to 25° C.

### Effect of the Invention

According to one embodiment of the present invention, low-cost control for operating a heater on the basis of a battery with the lowest battery temperature in a power storage module including a plurality of batteries can be achieved. Specifically, control for operating a heater on the basis of a battery with the lowest battery temperature by using voltage sensors and a current sensor included in a power storage module can be achieved. A power storage module that can control operation of a heater on the basis of a battery with the lowest battery temperature by using voltage sensors and a current sensor connected to a plurality of batteries connected in series can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1C are diagrams illustrating a structure example of a power storage module.

FIG. 2 is a diagram showing a temperature control flow in charging of a power storage module.

FIG. 3A and FIG. 3B are diagrams showing a relation between temperatures of batteries and dQ/dV.

FIG. 4 is a diagram showing a temperature control flow in charging of a power storage module.

FIG. 5 is a diagram showing a temperature control flow in charging of a power storage module.

FIG. 6 is a diagram showing a temperature control flow in charging of a power storage module.

FIG. 7A is a diagram showing a lookup table stored in an IC included in a control circuit of a power storage module, and FIG. 7B is a diagram showing part of a temperature control flow in charging of the power storage module.

FIG. 8 is a diagram illustrating a structure example of a power storage module.

FIG. 9A and FIG. 9B are diagrams illustrating structure examples of a power storage module.

FIG. 10 is a diagram illustrating a structure example of a power storage module.

FIG. 11A to FIG. 11D are diagrams illustrating a TCO element.

FIG. 12A to FIG. 12E are diagrams illustrating a TCO element.

FIG. 13A is a diagram illustrating a structure example of a power storage module, and FIG. 13B and FIG. 13C are diagrams each illustrating an FET.

FIG. 14 is a diagram illustrating a structure example of a power storage module.

FIG. 15 is a diagram illustrating a structure example of a power storage module.

FIG. 16 is a diagram illustrating a structure example of a power storage module.

FIG. 17 is a diagram illustrating a structure example of a power storage module.

FIG. 18A is an exploded perspective view of a coin-type secondary battery, FIG. 18B is a perspective view of the coin-type secondary battery, and FIG. 18C is a cross-sectional perspective view thereof.

FIG. 19A illustrates an example of a cylindrical secondary battery. FIG. 19B illustrates the example of the cylindrical secondary battery. FIG. 19C illustrates an example of a plurality of cylindrical secondary batteries. FIG. 19D illustrates an example of a power storage module including the plurality of cylindrical secondary batteries.

FIG. 20A and FIG. 20B are diagrams illustrating examples of a secondary battery, and FIG. 20C is a diagram illustrating the internal state of a secondary battery.

FIG. 21A to FIG. 21C are diagrams illustrating an example of a secondary battery.

FIG. 22A and FIG. 22B are diagrams illustrating external views of a secondary battery.

FIG. 23A to FIG. 23C are diagrams illustrating a method for fabricating a secondary battery.

FIG. 24A to FIG. 24C illustrate structure examples of a battery pack.

FIG. 25A is a perspective view of a power storage module of one embodiment of the present invention, FIG. 25B is a block diagram of the power storage module, and FIG. 25C is a block diagram of a vehicle including the power storage module.

FIG. 26A to FIG. 26D are diagrams illustrating examples of transport vehicles. FIG. 26E is a diagram illustrating an example of an artificial satellite.

FIG. 27A and FIG. 27B are diagrams illustrating power storage devices of one embodiment of the present invention.

FIG. 28A is a diagram illustrating an electric bicycle, FIG. 28B is a diagram illustrating a secondary battery of an electric bicycle, and FIG. 28C is a diagram illustrating an electric motorcycle.

FIG. 29A to FIG. 29D are diagrams illustrating examples of electronic devices.

FIG. 30A illustrates examples of wearable devices, FIG. 30B is a perspective view of a watch-type device, and FIG. 30C is a diagram illustrating a side surface of the watch-type device.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

The position, size, range, and the like of each component illustrated in drawings do not represent the actual position, size, range, and the like in some cases for easy understanding. Therefore, the disclosed invention is not necessarily limited to the position, size, range, and the like disclosed in drawings.

Note that in this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or claims in some cases.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, terms for describing positioning, such as “over”, “under”, “above”, and “below”, are sometimes used for convenience to describe the positional relation between components with reference to drawings. The positional relation between components is changed as appropriate in accordance with the direction in which the components are described. Thus, the positional relation is not limited to the terms described in this specification and the like, and can be described with another term as appropriate depending on the situation. For example, the expression “an insulator positioned over a conductor” can be replaced with the expression “an insulator positioned under a conductor” when the direction of a drawing illustrating these components is rotated by 180°.

Note that in this specification and the like, the term such as “over” or “below” do not necessarily mean that a component is placed “directly on” or “directly under” another component. For example, the expression “a gate electrode over a gate insulating film” does not exclude the case where there is an additional component between the gate insulating film and the gate electrode.

In this specification and the like, the terms such as “electrode” and “wiring” do not limit the functions of the components. For example, an “electrode” is used as part of a “wiring” in some cases, and vice versa. Furthermore, the terms “electrode” and “wiring” also include the case where a plurality of “electrodes” and “wirings” are formed in an integrated manner, for example.

Functions of a “source” and a “drain” are sometimes switched when a transistor of opposite polarity is used or when the direction of a current is changed in circuit operation, for example. Therefore, the terms “source” and “drain” can be switched in this specification.

Note that in this specification and the like, the expression “electrically connected” includes the case where components are connected through “an object having any electric function”. Here, there is no particular limitation on the “object having any electric function” as long as electric signals can be transmitted and received between components that are connected through the object. Examples of the “object having any electric function” include a switching element such as a transistor, a resistor, an inductor, a capacitor, and other elements with a variety of functions as well as an electrode and a wiring.

### Embodiment 1

This embodiment will be described below.

### Power Storage Module 100

A power storage module of this embodiment will be described below.

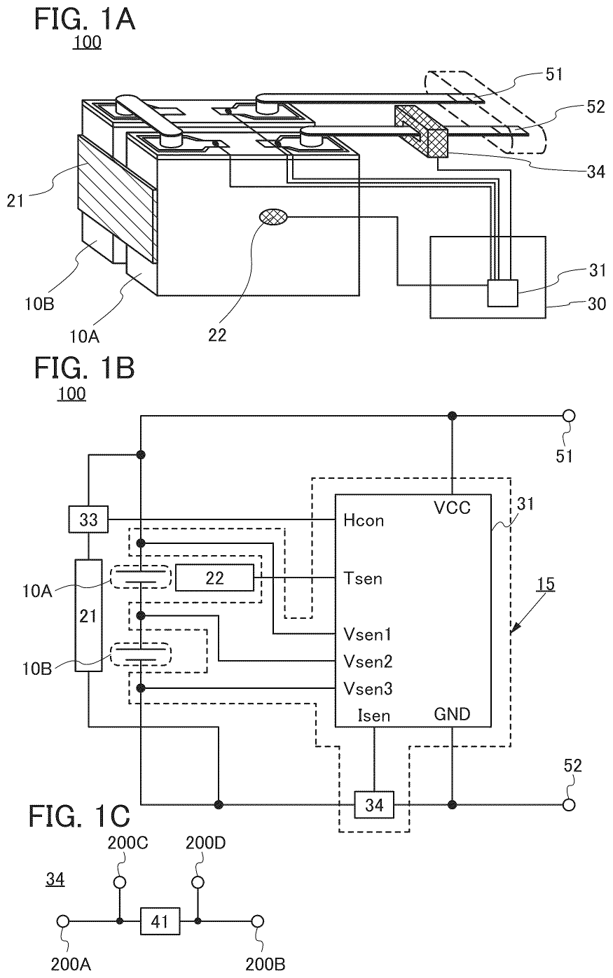

FIG. 1A to FIG. 1C illustrate a structure example of a power storage module 100 of one embodiment of the present invention. FIG. 1A illustrates a battery 10A, a battery 10B, a heater 21, a temperature sensor 22, an IC (Integrated Circuit) 31, and a current sensing element 34 included in the power storage module 100. In the drawing, the battery 10A and the battery 10B are connected in series. Although an example in which two batteries are included in the power storage module 100 of one embodiment of the present invention is illustrated, the number of batteries may be three or more. In describing contents common to the battery 10A and the battery 10B, the term “battery 10” is used in some cases.

As illustrated in FIG. 1A, the heater 21 and the temperature sensor 22 are preferably provided close to the battery 10. In the power storage module of one embodiment of the present invention, the number of temperature sensors 22 is smaller than the number of batteries 10. Thus, the temperature sensor 22 is preferably provided adjacent to the battery 10A or the battery 10B. FIG. 1A and FIG. 1B illustrate an example in which the temperature sensor 22 is provided close to the battery 10A. In this specification, the expression “provided close to” indicates being provided at a distance of preferably less than or equal to 100 mm, further preferably less than or equal to 50 mm, still further preferably greater than or equal to 0 mm and less than or equal to 30 mm. Note that in the case of being provided at a distance of 0 mm means being provided at a position in direct contact with each other.

In other words, the heater 21 and the temperature sensor 22 are not necessarily in direct contact with the battery 10. For example, when the heater 21 is provided inside the power storage module 100 at a position where it can heat the battery 10, the heater 21 is not necessarily in direct contact with the battery 10. For another example, when the temperature sensor 22 is provided at a position where it can measure the temperature of the battery 10, the temperature sensor 22 is not necessarily in direct contact with the battery 10.

The heater 21 is electrically connected to the IC 31. The temperature sensor 22 is also electrically connected to the IC 31.

As illustrated in FIG. 1A, the IC 31 is preferably provided on a circuit board 30. In addition to the IC 31, any one or more of an FET (Field effect transistor), a current sensing element, a thermal cut off (TCO) element, and the like described later can be provided on the circuit board 30.

FIG. 1B is a circuit diagram illustrating the electrical connection relation of the battery 10A, the battery 10B, the heater 21, the temperature sensor 22, the IC 31, an FET 33, the current sensing element 34, an external terminal 51, and an external terminal 52 included in the power storage module 100.

The external terminal 51 is electrically connected to a positive electrode terminal of the battery 10A, and the external terminal 52 is electrically connected to a negative electrode terminal of the battery 10B. The external terminal 51 and the external terminal 52 of the power storage module 100 are electrically connected to a power consumption portion included in an electronic device, a vehicle, or the like provided with the power storage module 100. Note that the power consumption portion refers to a CPU, a memory, a display, or an inverter in an electronic device or refers to a motor, a light, power steering, or an inverter in a vehicle, for example.

In the power storage module 100 illustrated in FIG. 1B, the positive electrode terminal of the battery 10A is electrically connected to a VCC terminal of the IC 31, and the negative electrode terminal of the battery 10B is electrically connected to a GND terminal of the IC 31.

One of a source and a drain of the FET 33 is electrically connected to the battery 10A, the other of the source and the drain of the FET 33 is electrically connected to one terminal of the heater 21, and a gate of the FET 33 is electrically connected to an Hcon terminal of the IC 31. The other terminal of the heater 21 is electrically connected to the negative electrode terminal of the battery 10B. With such a connection relation, the IC 31 can control the on and off states of the heater 21 through the FET 33.

As the heater 21, for example, a PTC (Positive Temperature Coefficient) thermistor can be used. As the heater 21, instead of a PTC thermistor, a resistor whose resistance is substantially constant irrespective of temperatures may be used.

As illustrated in FIG. 1A, a structure can be employed in which the outside of the battery 10 is directly heated using the plate-like heater 21. Alternatively, a structure may be employed in which heat emitted from the heater 21 is transferred to the battery 10 through a heat transfer medium, so that the battery 10 is indirectly heated. As the heat transfer medium, a solid-state member having a high heat-transferring property, such as a metal, may be used. Alternatively, as the heat transfer medium, a liquid medium or a gas medium may be used.

The temperature sensor 22 is electrically connected to a Tsen terminal of the IC 31. Although the connection between the temperature sensor 22 and the IC 31 is shown by one line in the drawing, the temperature sensor 22 and the IC 31 may be connected by two connection lines.

As the temperature sensor 22, for example, an NTC (Negative Temperature Coefficient) thermistor is used. That is, an NTC element can be used as the temperature sensor 22. An NTC thermistor is a thermistor whose resistance decreases with increasing temperatures. Note that the temperature sensor 22 is not limited to an NTC thermistor and another kind of temperature sensor such as a PTC thermistor or a thermocouple may be used.

The IC 31 has a function of sensing each of the voltages of the battery 10A and the battery 10B connected in series. In FIG. 1B, the positive electrode terminal of the battery 10A is electrically connected to a Vsen1 terminal of the IC 31, a negative electrode terminal of the battery 10A and a positive electrode terminal of the battery 10B are electrically connected to a Vsen2 terminal of the IC 31, and the negative electrode terminal of the battery 10B is electrically connected to a Vsen3 terminal of the IC 31. A wiring connected to the Vsen1 terminal, a wiring connected to the Vsen2 terminal, and a wiring connected to the Vsen3 terminal are each referred to as a wiring for voltage sensing. Including such a wiring for voltage sensing enables voltage sensors included in the IC 31 to sense voltages of the battery 10A and the battery 10B. In other words, the IC 31 includes the voltage sensor that senses the voltage of the battery 10A and the voltage sensor that senses the voltage of the battery 10B. Note that in the case where the series number of the batteries 10 connected in series is three or more, the wirings for voltage sensing are preferably provided in accordance with the series number.

The IC 31 has a function of sensing a current flowing through the battery 10A and the battery 10B connected in series. In FIG. 1B, the current sensing element 34 is electrically connected to an Isen terminal of the IC 31. The current sensing element 34 is also referred to as a current sensor.

As the current sensing element 34, a hall-type current sensor or a shunt-resistor-type sensor can be used. In the case where the hall-type current sensor is used as the current sensing element 34, a wiring electrically connecting the negative electrode terminal of the battery 10B and the external terminal 52 can be provided to pass through the inside of the current sensing element 34.

In the case where a shunt-resistor-type sensor is used as the current sensing element 34, the current sensing element 34 includes a resistor 41 (sometimes referred to as a shunt resistor) as illustrated in FIG. 1C, a terminal 200A of the resistor 41 included in the current sensing element 34 is electrically connected to the negative electrode terminal of the battery 10B, and a terminal 200B is electrically connected to the external terminal 52. A terminal 200C and a terminal 200D of the resistor included in the current sensing element 34 are electrically connected to the Isen terminal and an Isen′ terminal (not illustrated) of the IC 31, respectively. Note that in the structures illustrated in FIG. 1B and FIG. 1C, a wiring between the terminal 200D and the IC 31 may be omitted, and a wiring connected to the GND terminal of the IC 31 may be used for current sensing.

A circuit including the IC 31, the wirings for voltage sensing, and the current sensing element 34 described above is referred to as a control circuit 15 of the battery 10. That is, the control circuit 15 included in the power storage module 100 illustrated in FIG. 1B includes the voltage sensor that senses the voltage of the battery 10A, the voltage sensor that senses the voltage of the battery 10B, the wirings for voltage sensing, and the current sensor that senses the current flowing through the battery 10A and the battery 10B. An IC other than the IC 31, for example, a cell balancing IC or a fuel gauge IC may be included in the control circuit 15.

In this specification, a terminal refers to a portion for electrically connecting a battery, an IC, an FET element, or the like, and the shape of the terminal is not particularly limited. Any of terminals having various shapes such as a bolt shape, a wire shape, a flat plate shape, a ring shape, a socket shape, a pin shape, a solder hemispherical shape used for a BGA (Ball Grid Array), a flat plate shape used for an LGA (Land Grid Array), and a through-hole and a land (also referred to as a pad) of a PCB substrate can be used. Note that in a battery, part of the exterior body of the battery functions as a positive electrode terminal or a negative electrode terminal in some cases; in such a case, part of the exterior body of the battery can be used as a positive electrode terminal or a negative electrode terminal.

The IC 31 preferably has a function of protecting and a function of controlling the battery 10. The protection function can include, for example, one or more of overcharge protection, overdischarge protection, overcharge current protection, overdischarge current protection, and overheat protection of the battery 10. The control function can include one or more of charge control, discharge control, and cell balance control. That is, the IC 31 is preferably a battery control IC. Furthermore, the IC 31 is preferably a battery protection IC. Note that in the case where the IC 31 has a function of mainly controlling cell balance, the IC 31 can also be referred to as a cell balance control IC.

The IC 31 preferably has a function of a microcontroller. In the case where the IC 31 has a function of a microcontroller, the IC 31 includes a CPU, a memory, a clock generation circuit, an input portion, and an output portion. The input portion and the output portion are collectively referred to as an I/O portion in some cases. The IC 31 can operate in accordance with a program held in the memory. For example, in the case where the IC 31 senses that the temperature of the battery 10 is lower than or equal to a predetermined temperature through the temperature sensor 22, the IC 31 can operate the heater 21 on the basis of sensed temperature information. In the case where the IC 31 senses that the temperature of the battery 10 is higher than or equal to a predetermined temperature through the temperature sensor 22, the IC 31 can stop the heater 21 on the basis of sensed temperature information.

### dQ/dV

In the case where the control circuit 15 includes the IC 31 and the IC 31 has a function of a microcontroller, dQ/dV can be calculated from a value of a voltage of the battery 10 and a value of a current flowing through the battery 10 that are sensed by the IC 31. Furthermore, dQ/dV that is calculated can be stored as time-series data in a memory included in the microcontroller, and the stored dQ/dV time-series data can be analyzed. As the analysis of the dQ/dV time-series data, a peak voltage of dQ/dV can be calculated. The IC 31 can sense each of the values of the voltages of the battery 10A and the battery 10B, so that the peak voltage of dQ/dV of each of the battery 10A and the battery 10B can be calculated.

Note that in this specification, a peak voltage of dQ/dV refers to a voltage at which dQ/dV time-series data at a certain voltage width reaches a local maximum value. The voltage width can be, for example, a voltage width of 0.1 V, a voltage width of 0.05 V, a voltage width of 0.03 V, a voltage width of 0.02 V, or a voltage width of 0.01 V. Note that the peak voltage may be calculated every time dQ/dV is calculated; alternatively, the peak voltage may be calculated every certain period. For example, in the case where the peak voltage is calculated when a voltage of the battery 10A is 3.80 V, a voltage at which dQ/dV reaches the local maximum value ranging from 3.75 V to 3.80 V (a voltage width of 0.05 V) can be regarded as the peak voltage. In the case where the peak voltage is calculated when a voltage of the battery 10A is 3.81 V, a voltage at which dQ/dV reaches the local maximum value ranging from 3.76 V to 3.81 V (a voltage width of 0.05 V) can be regarded as the peak voltage.

FIG. 1A and FIG. 1B illustrate a structure example in which the number of temperature sensors 22 is smaller than the number of batteries 10 in the power storage module 100. In such a case, it is probable that the batteries in the power storage module might have different battery temperatures from each other depending on the location where the batteries are provided. That is, variations in battery temperatures may occur. In such a case, when a battery with a low temperature is included in the plurality of batteries, degradation of the battery capacity of the battery with a low temperature might accelerate. In addition, the risk of lithium being deposited on a negative electrode due to the low temperature might increase.

In the case where the temperatures of the plurality of batteries vary, a conceivable structure is such that the temperature sensor 22 is provided for each of the plurality of batteries 10 and each of the temperature sensors 22 is connected to the IC 31 to control the temperature. However, in the case where the temperature sensor 22 is provided for each of the plurality of batteries 10 included in the power storage module 100, the manufacturing cost is increased. As the example described in this embodiment, an example in which the number of batteries is two is described in order to avoid complexity of the description, while in some cases, approximately 100 batteries connected in series are used in an EV or the like; in such a case, the burden on the manufacturing cost due to the provision of temperature sensors for all the batteries is extremely large.

In this embodiment, even when the number of temperature sensors 22 is smaller than the number of batteries 10, variations in battery temperatures can be sensed and temperature control in charging can be performed.

As the temperature control in charging, the heater is operated on the basis of the battery with the lowest temperature among the plurality of batteries included in the power storage module, and the temperature of the battery with the lowest battery temperature is preferably kept higher than or equal to 0° C., further preferably kept higher than or equal to 5° C., still further preferably kept higher than or equal to 10° C., yet still further preferably kept higher than or equal to 15° C., yet still further preferably kept higher than or equal to 20° C., for example.

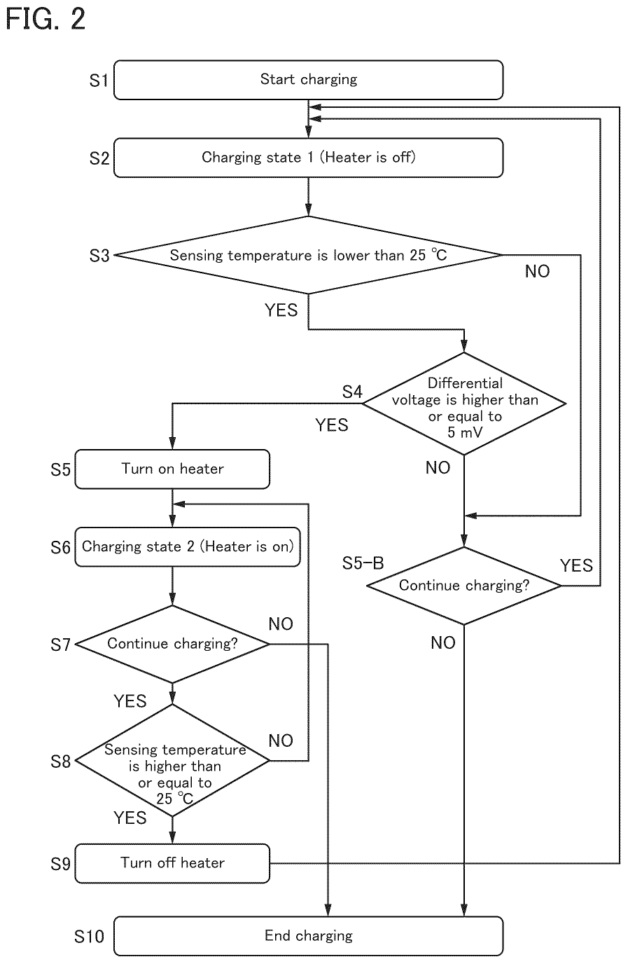

An example in which each of the peak voltages of dQ/dV of the battery 10A and the battery 10B is used for temperature control in charging of the power storage module 100 will be described with reference to FIG. 2 to FIG. 7.

### Temperature Control Flow 1

FIG. 2 is a diagram showing an example of a temperature control flow in charging of the power storage module 100.

FIG. 2 shows the temperature control flow for controlling the temperature of the battery 10 in charging the power storage module 100 illustrated in FIG. 1B.

In Step S1 in FIG. 2, charging of the battery 10A and the battery 10B included in the power storage module 100 is started. Accordingly, the power storage module 100 is in a charging state 1 in Step S2. In the charging state 1, the heater 21 is off.

In Step S3, whether the sensing temperature of the temperature sensor 22 is lower than a first temperature is determined. The first temperature can be a given temperature higher than or equal to 20° C. and lower than or equal to 35° C. The temperature control flow in FIG. 2 shows an example of the case where the first temperature is set to 25° C. Here, in the case where the sensing temperature of the temperature sensor 22 is lower than 25° C. (in the case of YES), the process proceeds to Step S4. In the case where the sensing temperature of the temperature sensor 22 is higher than or equal to 25° C. (in the case of NO), the process proceeds to Step S5-B.

In Step S4, a determination is made on the basis of the peak voltage of dQ/dV. Specifically, whether a differential voltage between the peak voltage of dQ/dV of the battery 10A (a first peak voltage of dQ/dV) and the peak voltage of dQ/dV of the battery 10B (a second peak voltage of dQ/dV) is higher than or equal to 5 mV is determined. In the case where the differential voltage is higher than or equal to 5 mV (in the case of YES), the process proceeds to Step S5. In the case where the differential voltage is lower than 5 mV (in the case of NO), the process proceeds to Step S5-B. Note that as a determination value of the differential voltage in Step S4, the above-described 5 mV is an example, and the determination value can be set freely in accordance with the battery characteristics of the battery 10. For example, as the determination value described above, a differential voltage corresponding to the case where the difference between battery temperatures of the battery 10A and the battery 10B in charging with a charge current higher than or equal to 0.1 C and lower than or equal to 0.5 C is 5° C. is preferably used, 4° C. is further preferably used, 3° C. is still further preferably used, 2° C. is yet still further preferably used, 1° C. is yet still further preferably used, and 0.1° C. is yet still further preferably used. Note that the peak voltage of dQ/dV refers to, as described above, a voltage at which dQ/dV time-series data at a certain voltage width reaches a local maximum value.

In Step S5, the heater 21 is turned on by a signal from the IC 31. In the structure illustrated in FIG. 1B, when the IC 31 turns on the FET 33, a current flows through the heater 21, so that the heater 21 is turned on. Accordingly, the power storage module 100 is in a charging state 2 in Step S6. In the charging state 2, the heater 21 is on.

In Step S5-B, whether charging of the battery 10A and the battery 10B is continued is checked. In the case where charging of the battery 10A and the battery 10B is continued (in the case of YES), the process returns to Step S2 and the charging state 1 is continued. In the case where charging of the battery 10A and the battery 10B is stopped (in the case of NO), the process proceeds to Step S10, the temperature control flow in charging ends, and charging ends.

In Step S7 following Step S6, whether charging of the battery 10A and the battery 10B is continued is checked. In the case where charging of the battery 10A and the battery 10B is continued (in the case of YES), the process proceeds to Step S8. In the case where charging of the battery 10A and the battery 10B is stopped (in the case of NO), the process proceeds to Step S10, the temperature control flow in charging ends, and charging ends.

In Step S8, whether the sensing temperature of the temperature sensor 22 is higher than or equal to the first temperature is determined. As in Step S3 in FIG. 2, the example of the case where the first temperature is set to 25° C. is shown. Here, in the case where the sensing temperature of the temperature sensor 22 is higher than or equal to 25° C. (in the case of YES), the process proceeds to Step S9. In the case where the sensing temperature of the temperature sensor 22 is lower than 25° C. (in the case of NO), the process returns to Step S6 and the charging state 2 is continued.

In Step S9, the heater 21 is turned off by a signal from the IC 31. In the structure illustrated in FIG. 1B, when the IC 31 turns off the FET 33, the heater 21 is turned off. Accordingly, the power storage module 100 is in the charging state 1 in Step S2.

In this manner, each of the peak voltages of dQ/dV of the battery 10A and the battery 10B can be used for temperature control in charging of the power storage module 100.

### dQ/dV Differential Voltage

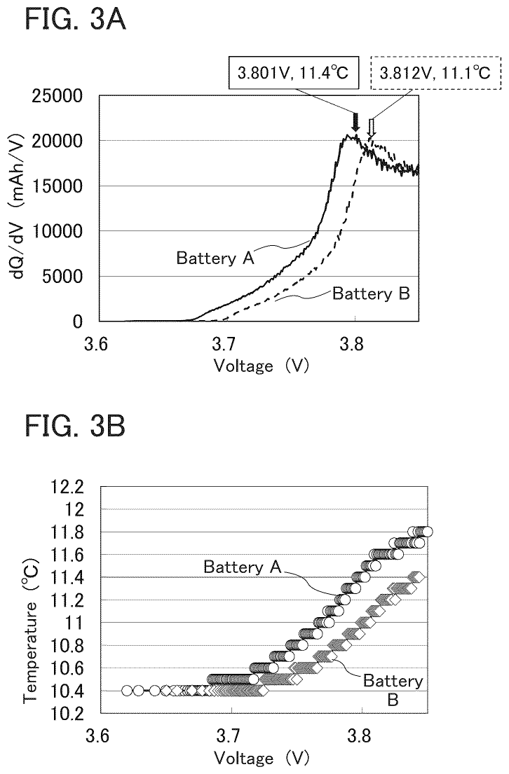

As an example of the relation between battery temperatures and dQ/dV, FIG. 3A is a graph showing dQ/dV in charging of a battery A and a battery B. FIG. 3B is a graph showing battery temperatures in charging in FIG. 3A.

The battery A and the battery B have different charging environments, and a tape for heat retention is wound around the battery A. Thus, as shown in FIG. 3B, an increase in the temperature of the battery A in charging is faster than an increase in the temperature of the battery B.

In this case, as illustrated in FIG. 3A, the graph shape of dQ/dV of the battery A is different from the graph shape of dQ/dV of the battery B, and the battery A with a high temperature exhibits a shift to the low voltage side. In the graph in FIG. 3A, the peak voltage of dQ/dV of the battery A is 3.801 V, and the temperature of the battery A in this case is 11.4° C. In the graph in FIG. 3A, the peak voltage of dQ/dV of the battery B is 3.812 V, and the temperature of the battery B in this case is 11.1° C. Thus, the differential voltage between the peak voltage of dQ/dV of the battery A and the peak voltage of dQ/dV of the battery B is 0.011 V.

### Temperature Control Flow 2

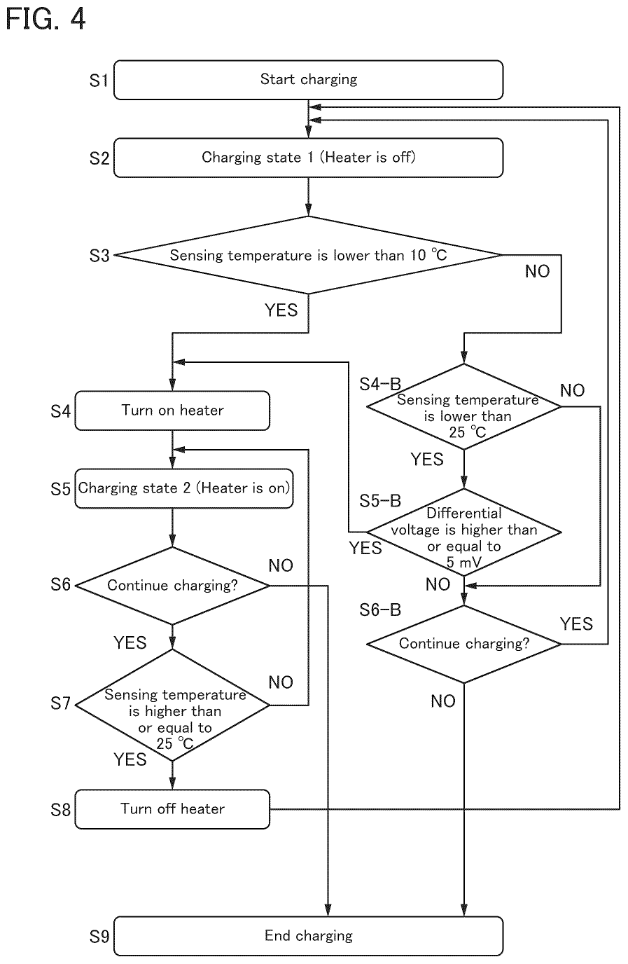

FIG. 4 is a diagram showing an example of a temperature control flow in charging of the power storage module 100 that is different from the temperature control flow 1.

FIG. 4 shows the temperature control flow for controlling the temperature of the battery 10 in charging the power storage module 100 illustrated in FIG. 1B.

In Step S1 in FIG. 4, charging of the battery 10A and the battery 10B included in the power storage module 100 is started. Accordingly, the power storage module 100 is in the charging state 1 in Step S2. In the charging state 1, the heater 21 is off.

In Step S3, whether the sensing temperature of the temperature sensor 22 is lower than a second temperature is determined. The second temperature can be a given temperature higher than or equal to 0° C. and lower than or equal to 10° C. The temperature control flow in FIG. 4 shows the example of the case where the second temperature is set to 10° C. Here, in the case where the sensing temperature of the temperature sensor 22 is lower than 10° C. (in the case of YES), the process proceeds to Step S4. In the case where the sensing temperature of the temperature sensor 22 is higher than or equal to 10° C. (in the case of NO), the process proceeds to Step S4-B.

In Step S4, the heater 21 is turned on by the signal from the IC 31. In the structure illustrated in FIG. 1B, when the IC 31 turns on the FET 33, a current flows through the heater 21, so that the heater 21 is turned on. Accordingly, the power storage module 100 is in the charging state 2 in Step S5. In the charging state 2, the heater 21 is on.

In Step S4-B, whether the sensing temperature of the temperature sensor 22 is lower than the first temperature is determined. As in Step S3 in FIG. 2, the example of the case where the first temperature is set to 25° C. is shown. Here, in the case where the sensing temperature of the temperature sensor 22 is lower than 25° C. (in the case of YES), the process proceeds to Step S5-B. In the case where the sensing temperature of the temperature sensor 22 is higher than or equal to 25° C. (in the case of NO), the process proceeds to Step S6-B.

In Step S5-B, a determination is made on the basis of the peak voltage of dQ/dV. As a determination method, as in Step S4 of the temperature control flow shown in FIG. 2, a differential voltage between the peak voltages of dQ/dV is preferably used.

In the case where the differential voltage is higher than or equal to 5 mV (in the case of YES) in Step S5-B in FIG. 4, the process proceeds to Step S4 and Step S5 in this order. In the case where the differential voltage is lower than 5 mV (in the case of NO), the process proceeds to Step S6-B. Note that the determination value of the differential voltage in Step S5-B is preferably similar to that in Step S4 in the temperature control flow shown in FIG. 2.

In Step S6 following Step S5, whether charging of the battery 10A and the battery 10B is continued is checked. In the case where charging of the battery 10A and the battery 10B is continued (in the case of YES), the process proceeds to Step S7. In the case where charging of the battery 10A and the battery 10B is stopped (in the case of NO), the process proceeds to Step S9, the temperature control flow in charging ends, and charging ends.

In Step S6-B, whether charging of the battery 10A and the battery 10B is continued is checked. In the case where charging of the battery 10A and the battery 10B is continued (in the case of YES), the process returns to Step S2 and the charging state 1 is continued. In the case where charging of the battery 10A and the battery 10B is stopped (in the case of NO), the process proceeds to Step S9, the temperature control flow in charging ends, and charging ends.

In Step S7, whether the sensing temperature of the temperature sensor 22 is higher than or equal to the first temperature is determined. As in Step S3 in FIG. 4, the example of the case where the first temperature is set to 25° C. is shown. Here, in the case where the sensing temperature of the temperature sensor 22 is higher than or equal to 25° C. (in the case of YES), the process proceeds to Step S8. In the case where the sensing temperature of the temperature sensor 22 is lower than 25° C. (in the case of NO), the process returns to Step S5 and the charging state 2 is continued.

In Step S8, the heater 21 is turned off by the signal from the IC 31. In the structure illustrated in FIG. 1B, when the IC 31 turns off the FET 33, the heater 21 is turned off. Accordingly, the power storage module 100 is in the charging state 1 in Step S2.

In this manner, each of the peak voltages of dQ/dV of the battery 10A and the battery 10B can be used for temperature control in charging of the power storage module 100.

### Temperature Control Flow 3

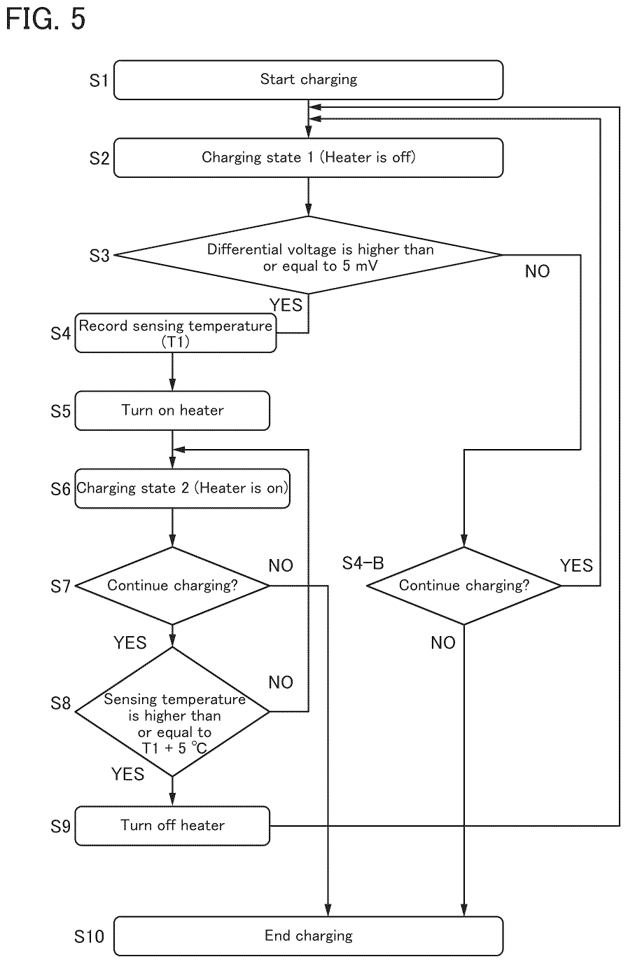

FIG. 5 is a diagram showing an example of a temperature control flow in charging of the power storage module 100 that is different from the temperature control flows 1 and 2.

FIG. 5 shows the temperature control flow for controlling the temperature of the battery 10 in charging the power storage module 100 illustrated in FIG. 1B.

In Step S1 in FIG. 5, charging of the battery 10A and the battery 10B included in the power storage module 100 is started. Accordingly, the power storage module 100 is in the charging state 1 in Step S2. In the charging state 1, the heater 21 is off.

In Step S3, a determination is made on the basis of the peak voltage of dQ/dV. As the determination method, as in Step S4 of the temperature control flow shown in FIG. 2, a differential voltage between the peak voltages of dQ/dV is preferably used.

In the case where the differential voltage is higher than or equal to 5 mV (in the case of YES) in Step S3 in FIG. 5, the process proceeds to Step S4. In the case where the differential voltage is lower than 5 mV (in the case of NO), the process proceeds to Step S4-B. Note that the determination value of the differential voltage in Step S3 is preferably similar to that in Step S4 in the temperature control flow shown in FIG. 2.

In Step S4 in FIG. 5, the sensing temperature of the temperature sensor 22 is recorded. The temperature at this time is T1.

Next, in Step S5, the heater 21 is turned on by the signal from the IC 31. In the structure illustrated in FIG. 1B, when the IC 31 turns on the FET 33, a current flows through the heater 21, so that the heater 21 is turned on. Accordingly, the power storage module 100 is in the charging state 2 in Step S6. In the charging state 2, the heater 21 is on.

In Step S4-B, whether charging of the battery 10A and the battery 10B is continued is checked. In the case where charging of the battery 10A and the battery 10B is continued (in the case of YES), the process returns to Step S2 and the charging state 1 is continued. In the case where charging of the battery 10A and the battery 10B is stopped (in the case of NO), the process proceeds to Step S10, the temperature control flow in charging ends, and charging ends.

In Step S7 following Step S6, whether charging of the battery 10A and the battery 10B is continued is checked. In the case where charging of the battery 10A and the battery 10B is continued (in the case of YES), the process proceeds to Step S8. In the case where charging of the battery 10A and the battery 10B is stopped (in the case of NO), the process proceeds to Step S10, the temperature control flow in charging ends, and charging ends.

In Step S8, whether the sensing temperature of the temperature sensor 22 is higher than or equal to T1+5° C. is determined. Here, in the case where the sensing temperature of the temperature sensor 22 is higher than or equal to T1+5° C. (in the case of YES), the process proceeds to Step S9. In the case where the sensing temperature of the temperature sensor 22 is lower than T1+5° C. (in the case of NO), the process returns to Step S6 and the charging state 2 is continued. Note that the determination condition in Step S8 is not limited to T1+5° C. and can be set to a given temperature of T1+3° C. to T1+10° C. Furthermore, the given temperature is not limited to an integer.

In Step S9, the heater 21 is turned off by the signal from the IC 31. In the structure illustrated in FIG. 1B, when the IC 31 turns off the FET 33, the heater 21 is turned off. Accordingly, the power storage module 100 is in the charging state 1 in Step S2.

In this manner, each of the peak voltages of dQ/dV of the battery 10A and the battery 10B can be used for temperature control in charging of the power storage module 100.

### Temperature Control Flow 4

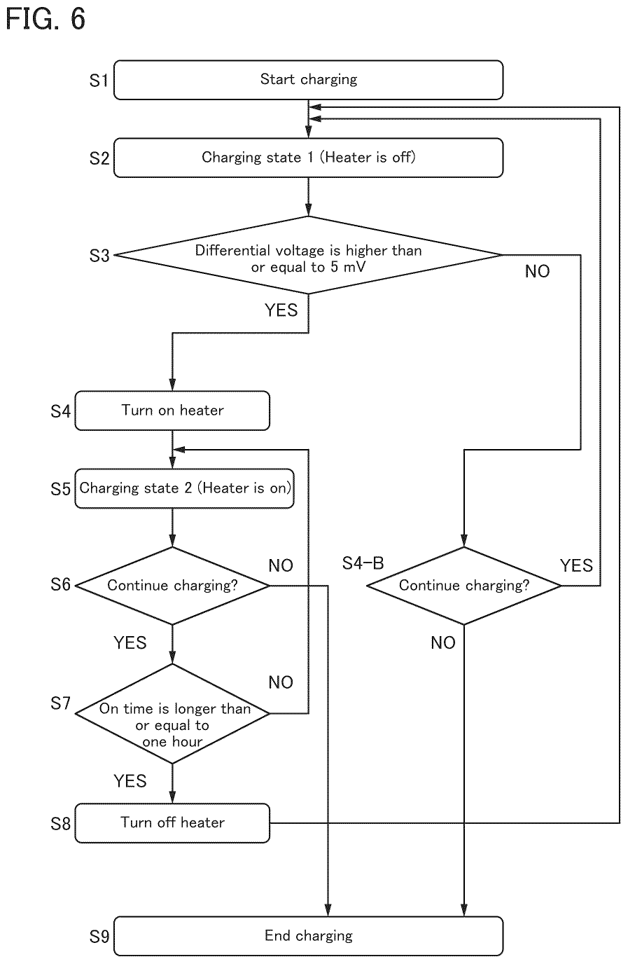

FIG. 6 is a diagram showing an example of a temperature control flow in charging of the power storage module 100 that is different from the temperature control flows 1 to 3.

FIG. 6 shows the temperature control flow for controlling the temperature of the battery 10 in charging the power storage module 100 illustrated in FIG. 1B.

In Step S1 in FIG. 6, charging of the battery 10A and the battery 10B included in the power storage module 100 is started. Accordingly, the power storage module 100 is in the charging state 1 in Step S2. In the charging state 1, the heater 21 is off.

In Step S3, a determination is made on the basis of the peak voltage of dQ/dV. As the determination method, as in Step S4 of the temperature control flow shown in FIG. 2, a differential voltage between the peak voltages of dQ/dV is preferably used.

In the case where the differential voltage is higher than or equal to 5 mV (in the case of YES) in Step S3 in FIG. 6, the process proceeds to Step S4. In the case where the differential voltage is lower than 5 mV (in the case of NO), the process proceeds to Step S4-B. Note that the determination value of the differential voltage in Step S3 is preferably similar to that in Step S4 in the temperature control flow shown in FIG. 2.

In Step S4, the heater 21 is turned on by the signal from the IC 31. In the structure illustrated in FIG. 1B, when the IC 31 turns on the FET 33, a current flows through the heater 21, so that the heater 21 is turned on. Accordingly, the power storage module 100 is in the charging state 2 in Step S5. In the charging state 2, the heater 21 is on.

In Step S4-B, whether charging of the battery 10A and the battery 10B is continued is checked. In the case where charging of the battery 10A and the battery 10B is continued (in the case of YES), the process returns to Step S2 and the charging state 1 is continued. In the case where charging of the battery 10A and the battery 10B is stopped (in the case of NO), the process proceeds to Step S10, the temperature control flow in charging ends, and charging ends.

In Step S6 following Step S5, whether charging of the battery 10A and the battery 10B is continued is checked. In the case where charging of the battery 10A and the battery 10B is continued (in the case of YES), the process proceeds to Step S7. In the case where charging of the battery 10A and the battery 10B is stopped (in the case of NO), the process proceeds to Step S9, the temperature control flow in charging ends, and charging ends.

In Step S7, elapsed time after turning on the heater 21 is determined. That is, elapsed time of the charging state 2 is determined. In the case where the time after turning on the heater 21 is longer than or equal to a certain time, e.g., longer than or equal to one hour (in the case of YES), the process proceeds to Step S8. In the case where the time after turning on the heater 21 is shorter than one hour (in the case of NO), the process returns to Step S5 and the charging state 2 is continued. Note that as a determination value of the elapsed time in Step S7, the above-described one hour is an example, and the determination value can be set freely in accordance with the temperature characteristics of the battery 10. For example, the time required for the temperature of the battery 10 to increase by 5° C. can be used as the determination value of the elapsed time.

In Step S8, the heater 21 is turned off by the signal from the IC 31. In the structure illustrated in FIG. 1B, when the IC 31 turns off the FET 33, the heater 21 is turned off. Accordingly, the power storage module 100 is in the charging state 1 in Step S2.

In this manner, each of the peak voltages of dQ/dV of the battery 10A and the battery 10B can be used for temperature control in charging of the power storage module 100.

### dQ/dV Lookup Table

In Step S4 in the temperature control flow 1 (FIG. 2), Step S5-B in the temperature control flow 2 (FIG. 4), Step S3 in the temperature control flow 3 (FIG. 5), and Step S3 in the temperature control flow 4 (FIG. 6), a method in which the differential voltage between the peak voltages of dQ/dV is used for determination is described. Another determination method using dQ/dV that can be used instead of this method will be described.

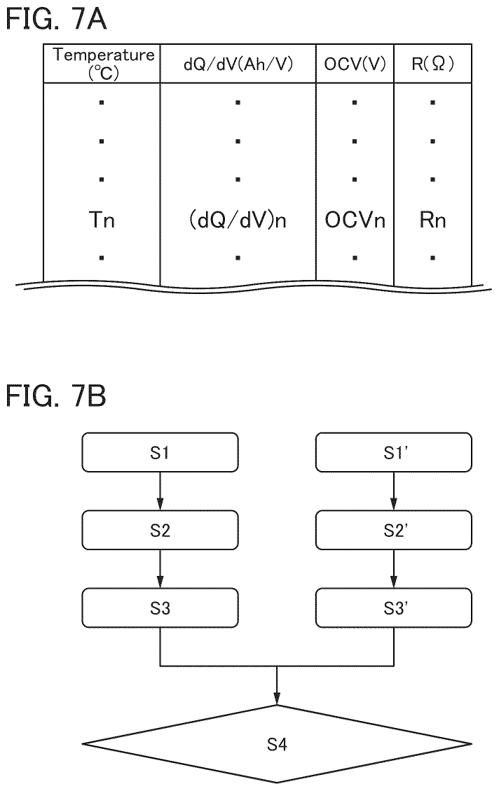

FIG. 7A is a diagram showing an example of a lookup table stored in the memory included in the IC 31. The lookup table includes data showing the relation between a temperature, dQ/dV, OCV (Open Circuit Voltage), and internal resistance R of the battery 10. The data of the lookup table is data obtained by using a battery for obtaining data that is fabricated under the same conditions as the battery 10 included in the power storage module 100, and is an accurate measurement value under various conditions (e.g., a temperature and a voltage). The data of the lookup table includes a data group of dQ/dV, OCV, and the internal resistance R for each of a plurality of temperatures, for example.

With use of this lookup table, the temperatures of the batteries 10 included in the power storage module 100 can be estimated. In addition, a variation in the temperatures of the batteries can be determined. The method will be described with reference to FIG. 7A and FIG. 7B.

In Step S1, the sensing temperature of the temperature sensor 22 is defined as Ta. The dQ/dV of the battery 10A is calculated and defined as (dQ/dV)a. The voltage and the current of the battery 10A at this time are defined as Va and Ia, respectively.

Next, in Step S2, data (dQ/dV) n that is the closest to the (dQ/dV) a is selected from the data group of a temperature Tn that is the closest to the Ta in the lookup table.

Next, in Step S3, Va′ is calculated using OCVn and internal resistance Rn, which are linked to the selected data, and the Ia. Note that Va′=OCV+Ia×R.

In Step S3, when a differential voltage ΔVa between Va and Va′ is high, the temperature of the battery 10A might be different from the sensing temperature of the temperature sensor 22. Note that ΔVa=Va−Va′.

Also for the battery 10B, data processing using the lookup table is performed as in Step S1 to Step S3 to calculate Vb′ (Step S1′ to Step S3′). Note that Vb′=OCV+Ib×R.

In Step S3′, when a differential voltage ΔVb between Vb and Vb′ is high, the temperature of the battery 10B might be different from the sensing temperature of the temperature sensor 22. Note that ΔVb=Vb−Vb′.

One or both of the differential voltage ΔVa calculated in Step S1 to Step S3 and the differential voltage ΔVb calculated in Step S1′ to Step S3′ in FIG. 7B can be used for determination in Step S4 in the temperature control flow 1 (FIG. 2), Step S5-B in the temperature control flow 2 (FIG. 4), Step S3 in the temperature control flow 3 (FIG. 5), and Step S3 in the temperature control flow 4 (FIG. 6).

For example, in Step S4 in FIG. 7B, one or both of the differential voltage ΔVa and the differential voltage ΔVb can be used such that the process proceeds to different flows between the case where the differential voltage is higher than or equal to 5 mV (in the case of YES) and the case where the differential voltage is lower than 5 mV (in the case of NO).

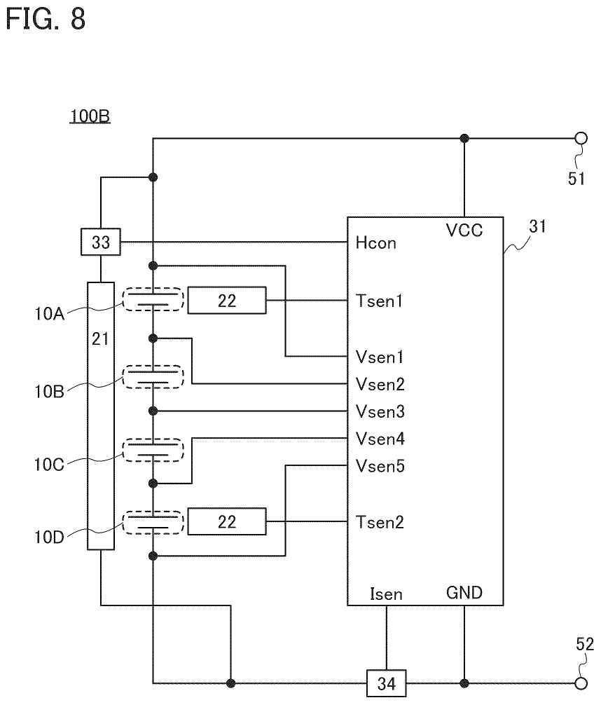

A modification example of the power storage module 100 illustrated in FIG. 1B will be described with reference to FIG. 8 to FIG. 17. Note that in the following description of the power storage module, the description of portions similar to those of the above power storage module is omitted in some cases.

### Power Storage Module 100B

A power storage module 100B illustrated in FIG. 8 is a modification example of the power storage module 100. Although the power storage module 100 illustrated in FIG. 1B is a structure example including two batteries 10, the power storage module of one embodiment of the present invention may include three or more batteries 10. For example, as in the power storage module 100B illustrated in FIG. 8, four batteries 10 may be included. For another example, 10 or more batteries 10, 20 or more batteries 10, 30 or more batteries 10, 40 or more batteries 10, 50 or more batteries 10, 60 or more batteries 10, 70 or more batteries 10, 80 or more batteries 10, 90 or more batteries 10, or 100 or more batteries 10 may be included.

Although the power storage module 100 illustrated in FIG. 1B is a structure example including one temperature sensor 22, two or more temperature sensors 22 may be included. For example, as in the power storage module 100B illustrated in FIG. 8, two temperature sensors 22 may be included. Note that the number of the temperature sensors 22 is preferably smaller than the number of the batteries 10 in terms of the manufacturing cost.

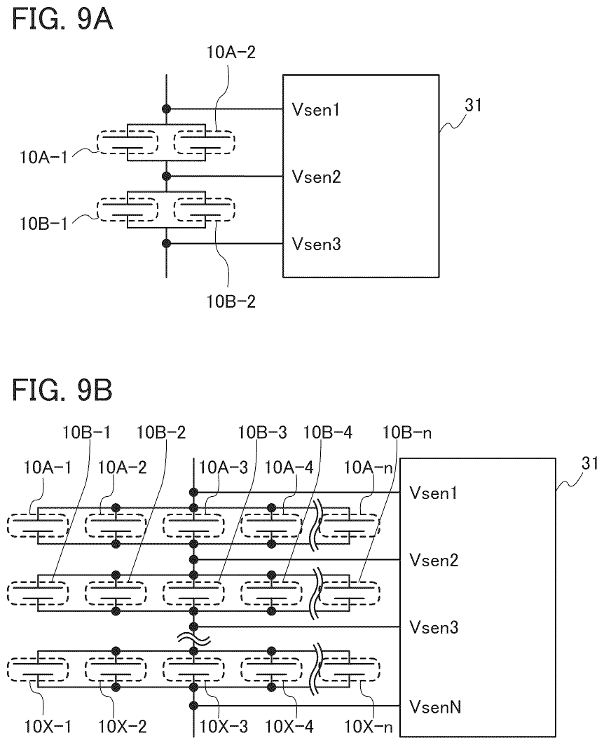

Note that the connection of the plurality of batteries 10 included in the power storage module of one embodiment of the present invention is not limited to the series connection illustrated in FIG. 1B and FIG. 8. For example, as illustrated in FIG. 9A, a battery 10A-1 and a battery 10A-2 that are connected in parallel and a battery 10B-1 and a battery 10B-2 that are connected in parallel can be connected in series. In that case, a positive electrode terminal of the battery 10A-1 and a positive electrode terminal of the battery 10A-2 are electrically connected to the Vsen1 terminal of the IC 31; a negative electrode terminal of the battery 10A-1, a negative electrode terminal of the battery 10A-2, a positive electrode terminal of the battery 10B-1, and a positive electrode terminal of the battery 10B-2 are electrically connected to the Vsen2 terminal of the IC 31; and a negative electrode terminal of the battery 10B-1 and a negative electrode terminal of the battery 10B-2 are electrically connected to the Vsen3 terminal of the IC 31. The connection between the plurality of batteries 10 illustrated in FIG. 9A is referred to as a connection in which two groups of two parallel connected batteries are connected in series.

The parallel number and/or the series number in the connection between the plurality of batteries 10 included in the power storage module of one embodiment of the invention may be larger than that in the connection illustrated in FIG. 9A, in which the two groups of two parallel connected batteries are connected in series. For example, as illustrated in FIG. 9B, n batteries 10 may be connected in parallel, and X stages of them may be connected in series; n and X are each a given number.

### Power Storage Module 100C

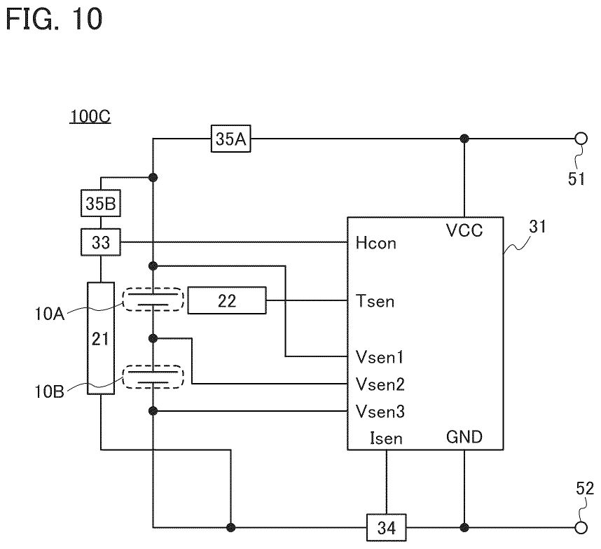

A power storage module 100C illustrated in FIG. 10 is a modification example of the power storage module 100. The power storage module 100C illustrated in FIG. 10 includes a TCO (Thermal Cut Off) element 35 (a TCO element 35A and a TCO element 35B) in addition to the components of the power storage module 100 illustrated in FIG. 1B.

The TCO element 35 has a function of blocking a current when the temperature is higher than a predetermined temperature. That is, the TCO element 35 has a function of blocking a current flowing through the TCO element 35 in overheating. Furthermore, when an overcurrent flows, the TCO element 35 may have a function of blocking a current flowing through the TCO element 35.

One terminal of the TCO element 35A is electrically connected to the positive electrode terminal of the battery 10A, and the other terminal of the TCO element 35A is electrically connected to the external terminal 51. The TCO element 35A is preferably provided close to the battery 10A or the battery 10B. With such a structure, a current can be blocked when the battery 10 is overheated, so that a safe power storage module can be obtained. Furthermore, a current can be blocked when an excessive current flows through the battery 10, so that a safe power storage module can be obtained.

One terminal of the TCO element 35B is electrically connected to the positive electrode terminal of the battery 10A, and the other terminal of the TCO element 35B is electrically connected to one of the source and the drain of the FET 33. The other of the source and the drain of the FET 33 is connected to one terminal of the heater 21. The TCO element 35B is preferably provided close to the heater 21. With such a structure, a current can be blocked when the heater 21 is overheated, so that a safe power storage module can be obtained.

### TCO Element

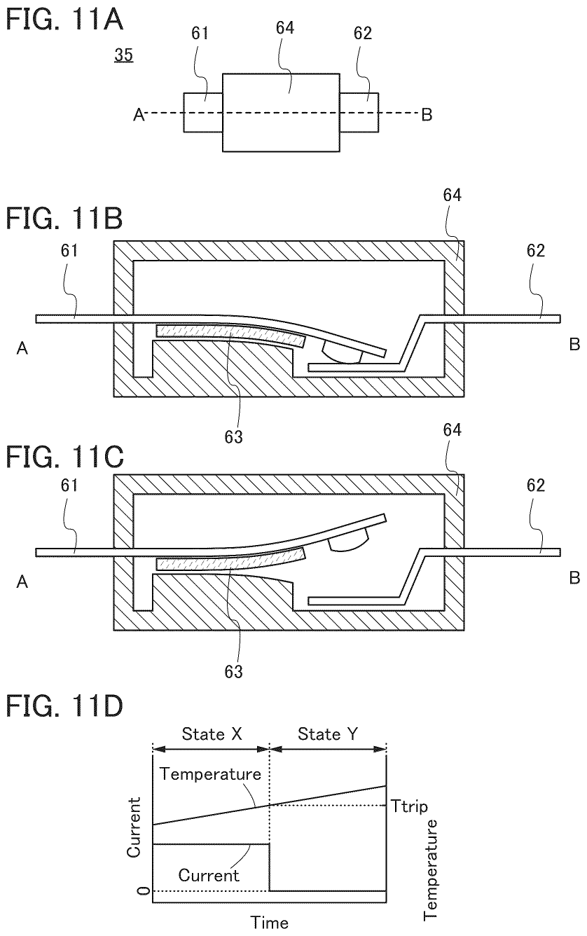

The structure and operation of the TCO element 35 will be described with reference to FIG. 11A to FIG. 11D. FIG. 11A is a top view of the TCO element 35. The TCO element 35 includes an exterior body 64, and a terminal 61 and a terminal 62 extending from the inside to the outside of the exterior body 64.

FIG. 11B and FIG. 11C are cross-sectional views of the TCO element 35 taken along the dashed line A-B in FIG. 11A. FIG. 11B illustrates a state where the terminal 61 and the terminal 62 included in the TCO element 35 are in contact with each other, and this state is referred to as a FIG. 11C illustrates a state where the terminal 61 and the terminal 62 included in the state X. TCO element 35 are not in contact with each other (are separated from each other), and this state is referred to as a state Y. The TCO element 35 is in either the state X or the state Y in accordance with the temperature of the TCO element 35. FIG. 11D is a graph showing the temperature of the TCO element 35 and a current flowing through the TCO element 35.

As illustrated in FIG. 11B and FIG. 11C, the TCO element 35 includes the terminal 61, the terminal 62, a bimetal 63, and the exterior body 64. The bimetal 63 includes two metal plates having different thermal expansion coefficients, and when the temperature of the TCO element 35 (more specifically, the temperature of the bimetal 63) is lower than or equal to a trip temperature Ttrip, the TCO element 35 has a shape in the state X illustrated in FIG. 11B, and when the temperature of the TCO element 35 is higher than the trip temperature Ttrip, the TCO element 35 has a shape in the state Y illustrated in FIG. 11C. FIG. 11D illustrates a case where the temperature of the TCO element 35 is gradually increased while a constant current is supplied to the TCO element 35. When the temperature of the TCO element 35 is lower than or equal to the trip temperature Ttrip, a current can flow through the TCO element 35 because the TCO element 35 has the shape illustrated in FIG. 11B (the state X). Meanwhile, when the temperature of the TCO element 35 is higher than the trip temperature Ttrip, no current can flow through the TCO element 35 because the TCO element 35 has the shape illustrated in FIG. 11C (the state Y). As described above, the TCO element 35 has a function of blocking a current when the temperature of the TCO element 35 is higher than a predetermined temperature; thus, it can be said that the TCO element 35 has an overheat protection function.

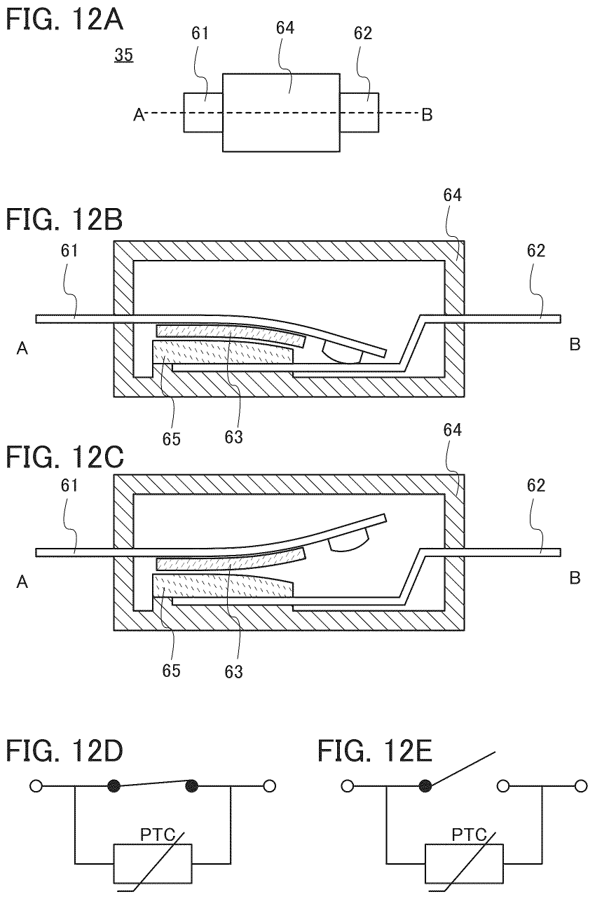

FIG. 12A to FIG. 12E are diagrams illustrating a modification example of the TCO element 35 illustrated in FIG. 11A to FIG. 11D.

FIG. 12A is a top view of the TCO element 35. The TCO element 35 includes the exterior body 64, and the terminal 61 and the terminal 62 extending from the inside to the outside of the exterior body 64.

FIG. 12B and FIG. 12C are cross-sectional views of the TCO element 35 taken along the dashed line A-B in FIG. 12A. FIG. 12B illustrates a state where the terminal 61 and the terminal 62 included in the TCO element 35 are in contact with each other, and this state is referred to as a state C. FIG. 12C illustrates a state where the terminal 61 and the terminal 62 included in the TCO element 35 are not in contact with each other (are separated from each other), and this state is referred to as a state D. The TCO element 35 is in either the state C or the state D in accordance with the temperature of the TCO element 35. FIG. 12D is a circuit diagram of the TCO element 35 in the state C, and FIG. 12E is a circuit diagram of the TCO element 35 in the state D.

As illustrated in FIG. 12B and FIG. 12C, the TCO element 35 includes a PTC portion 65 in addition to the terminal 61, the terminal 62, the bimetal 63, and the exterior body 64. As illustrated in FIG. 11B to FIG. 11D, the TCO element 35 whose temperature is lower than or equal to the trip temperature Ttrip has a shape in the state C illustrated in FIG. 12B, and the TCO element 35 whose temperature is higher than the trip temperature Ttrip has a shape in the state D illustrated in FIG. 12C. In both the state C and the state D, the terminal 61 and the terminal 62 are electrically connected to each other through the bimetal 63 and the PTC portion 65. In the case where the TCO element 35 has the above structure, the temperature of the PTC portion 65 is increased by resistance heating when an overcurrent flows through the TCO element 35. Here, when the temperature of the TCO element 35 (more specifically, the temperature of the bimetal 63) becomes higher than the trip temperature Ttrip, the shape changes from the state C to the state D. In other words, it can be said that the TCO element 35 illustrated in FIG. 12A to FIG. 12E is an element having an overheat protection function and an overcurrent protection function.

### Power Storage Module 100D

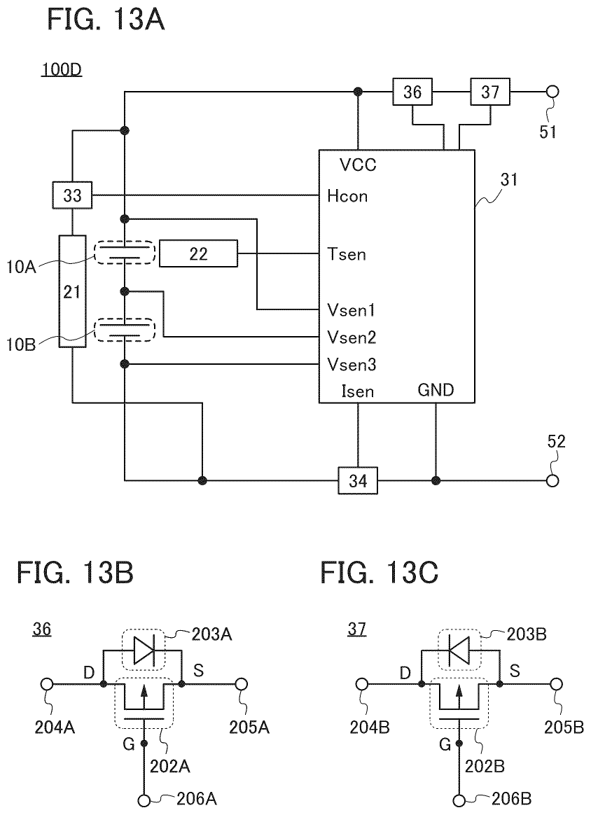

A power storage module 100D illustrated in FIG. 13A is a modification example of the power storage module 100. The power storage module 100D illustrated in FIG. 13A includes an FET 36 and an FET 37 in addition to the components illustrated in FIG. 1B. FIG. 13B is a diagram illustrating the FET 36, and FIG. 13C is a diagram illustrating the FET 37.

As illustrated in FIG. 13B, the FET 36 includes a transistor 202A, a diode 203A, a terminal 204A, a terminal 205A, and a terminal 206A. The terminal 204A is electrically connected to the battery 10A, the terminal 205A is electrically connected to the FET 37, and the terminal 206A is electrically connected to the IC 31. The terminal 204A is electrically connected to a drain (D) of the transistor 202A and an anode of the diode 203A. Note that a source and a drain of a transistor are sometimes interchangeable depending on the voltage applied therebetween; here, for easy understanding of a circuit structure, in a p-channel transistor, a terminal having a high potential in charging is called a source and the other terminal having a low potential in charging is called a drain. In an n-channel transistor, a terminal having a high potential is called a drain, and the other terminal having a low potential is called a source.

When the FET 36 has the structure illustrated in FIG. 13B, the FET 36 has a function of supplying a charge current of the battery 10, a function of blocking the charge current, and a function of supplying a discharge current of the battery 10.

As illustrated in FIG. 13C, the FET 37 includes a transistor 202B, a diode 203B, a terminal 204B, a terminal 205B, and a terminal 206B. The terminal 204B is electrically connected to the FET 36, the terminal 205B is electrically connected to the external terminal 51, and the terminal 206B is electrically connected to the IC 31. The terminal 204B is electrically connected to a drain (D) of the transistor 202B and a cathode of the diode 203B.

When the FET 37 has the structure illustrated in FIG. 13C, the FET 37 has a function of supplying a discharge current of the battery 10, a function of blocking the discharge current, and a function of supplying a charge current of the battery 10.

As described above, in the power storage module 100D illustrated in FIG. 13A, the FET 36 has the function of supplying a charge current of the battery 10, the function of blocking the charge current, and the function of supplying a discharge current of the battery 10. The FET 37 has the function of supplying a discharge current of the battery 10, the function of blocking the discharge current, and the function of supplying a charge current of the battery 10.

Although FIG. 13A illustrates an example in which one FET 36 and one FET 37 are included in the power storage module 100D, one embodiment of the present invention is not limited to this structure. In the power storage module, two FETs 36 may be connected in parallel and two FETs 37 may be connected in parallel. With such a structure, high-current charging and discharging can be easily performed.

### Power Storage Module 100E

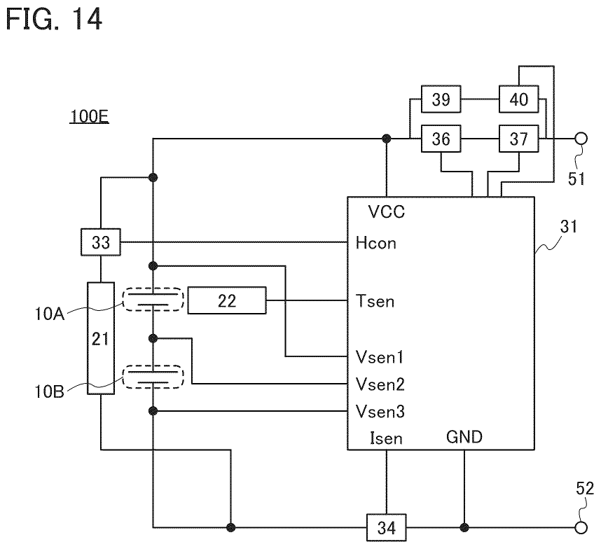

A power storage module 100E illustrated in FIG. 14 is a modification example of the power storage module 100.

FIG. 14 is a diagram illustrating a modification example of the power storage module 100D including the FET 36 and the FET 37 illustrated in FIG. 13A. The power storage module 100E illustrated in FIG. 14 includes a PTC element 39 and an FET 40 that are connected in parallel to the FET 36 and the FET 37. The PTC element 39 has a function of inhibiting an inrush current generated in starting an electronic device or a vehicle each including the power storage module 100E.

For example, in the case where the PTC element 39 is connected in series to the FET 36 and the FET 37, power loss due to the PTC element 39 occurs. By contrast, the structure having a parallel connection illustrated in FIG. 14 is preferable because controlling the on/off of the FET 40 allows the PTC element 39 to be used only at a required timing, so that power loss can be reduced.

Note that a relay can also be used for the FET 36, the FET 37, and the FET 40, as well as the components illustrated in FIG. 13B or FIG. 13C. As the relay, for example, a mechanical relay having a mechanism in which an electromagnet operates by an electric signal from a control IC (e.g., the IC 31) or the like, so that a switch is opened and closed can be used. The relay is preferably used as each of the FET 36, the FET 37, and the FET 40, in which case a large amount of current can easily flow.

### Power Storage Module 100F

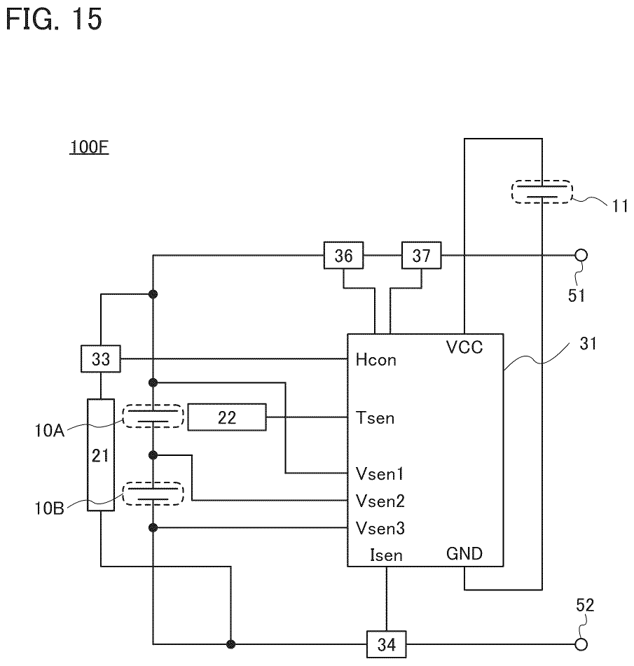

A power storage module 100F illustrated in FIG. 15 is a modification example of the power storage module 100.

The power storage module 100F illustrated in FIG. 15 includes a battery 11 in addition to the components illustrated in FIG. 13A. The battery 11 is electrically connected to neither the battery 10A nor the battery 10B, a positive electrode terminal of the battery 11 is electrically connected to the VCC terminal of the IC 31, and a negative electrode terminal of the battery 11 is electrically connected to the GND terminal of the IC 31. With such a structure, the IC 31 can be driven by the battery 11; thus, after the states of the battery 10A and the battery 10B are checked in advance, the FET 36 and the FET 37 can be controlled and charging or discharging of the battery 10A and the battery 10B can be started.

### Power Storage Module 100G

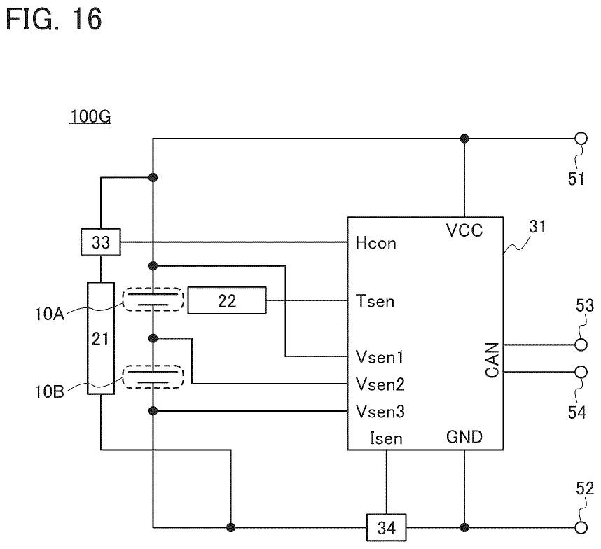

A power storage module 100G illustrated in FIG. 16 is a modification example of the power storage module 100. In addition to the components illustrated in FIG. 1B, a communication terminal 53 and a communication terminal 54 are included. As illustrated in FIG. 16, the power storage module of one embodiment of the present invention may include a communication terminal in addition to the external terminal 51 and the external terminal 52. For example, in the case where the IC 31 has a communication function such as a CAN, the IC 31 is electrically connected to the communication terminal 53 and the communication terminal 54 as illustrated in FIG. 16, and the communication terminal 53 and the communication terminal 54 can communicate with an electronic device or a vehicle each including the power storage module 100G.

### Power Storage Module 100H

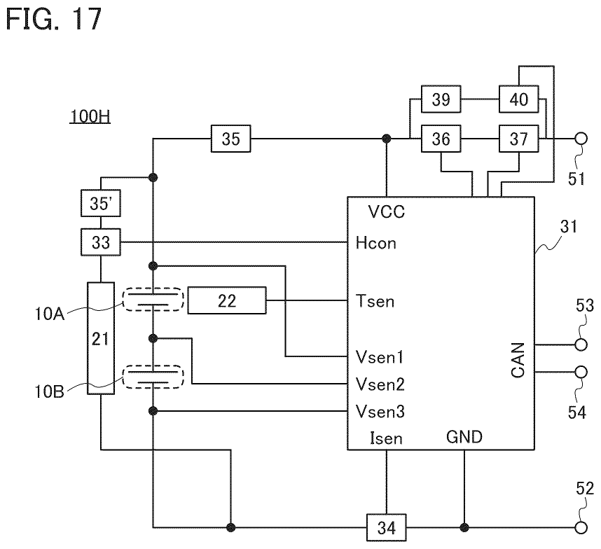

A power storage module 100H illustrated in FIG. 17 is a modification example of the power storage module 100.

Thus far, as examples of the power storage module 100 of one embodiment of the present invention, not only the example illustrated in FIG. 1B but also the examples including components such as the TCO element 35 are described with reference to FIG. 8 to FIG. 16. Note that the power storage module of one embodiment of the present invention is not limited to the structures of the power storage module 100B to the power storage module 100G separately illustrated in FIG. 8 to FIG. 16, and a plurality of components can be combined as illustrated in FIG. 17. As illustrated in FIG. 17, two TCO elements (the TCO element 35 and a TCO element 35′) may be included.

Although FIG. 1 to FIG. 17 illustrate the examples in which the FET 33, the TCO element 35, the FET 36, the FET 37, the PTC element 39, the FET 40, and the like are provided along a path (on a high potential side) between the battery 10 and the external terminal 51 and the current sensing element 34 is provided along a path (on a low potential side) between the battery 10 and the external terminal 52, one embodiment of the present invention is not limited to the examples. The FET 33, the TCO element 35, the FET 36, the FET 37, the PTC element 39, the FET 40, and the like may be provided along the path (on the low potential side) between the battery 10 and the external terminal 52. The current sensing element 34 may be provided along the path (on the high potential side) between the battery 10 and the external terminal 51.

The above is the description of the power storage module 100 of one embodiment of the present invention. Although a resistor, a capacitor, and the like are not illustrated along a path (a wiring) where the IC 31 and each component are electrically connected to each other in FIG. 1 to FIG. 17 for simplification of the description and easy viewing of the drawings, a resistor, a capacitor, and the like can be provided as appropriate. For example, when a wiring connected to a gate of the FET has a resistance of several tens of ohms to several kiloohms, oscillation of the FET can be inhibited in some cases.

The structure, method, and the like described in this embodiment can be used in an appropriate combination with structures, methods, and the like described in the other embodiments.

### Embodiment 2

This embodiment will describe components included in a lithium-ion battery, which is an example of a battery used as the battery 10. Although not described in this embodiment, a battery other than a lithium-ion battery, for example, a sodium-ion battery, a nickel-hydride battery, or a lead storage battery may be used as the battery 10.

The lithium-ion battery includes a negative electrode, a positive electrode, an electrolyte, a separator, and an exterior body.

### Negative Electrode

The negative electrode includes a negative electrode active material layer and a negative electrode current collector. The negative electrode active material layer includes a negative electrode active material and may further include a conductive material and a binder.

Metal foil can be used as the current collector, for example. The negative electrode can be formed by applying slurry onto the metal foil and drying the slurry. Note that pressing may be performed after drying. The negative electrode is a component obtained by forming an active material layer over the current collector.

Slurry refers to a material solution that is used to form the active material layer over the current collector and includes an active material, a binder, and a solvent, preferably also a conductive material mixed therewith. Slurry may also be referred to as slurry for an electrode or active material slurry; in some cases, slurry for forming a negative electrode active material layer is referred to as slurry for a negative electrode.

### Negative Electrode Active Material

As the negative electrode active material, for example, a carbon material or an alloy-based material can be used.

As the carbon material, for example, graphite (natural graphite and artificial graphite), graphitizing carbon (soft carbon), non-graphitizing carbon (hard carbon), carbon fiber (carbon nanotube), graphene, carbon black, or the like can be used.

Examples of graphite include artificial graphite and natural graphite. Examples of artificial graphite include mesocarbon microbeads (MCMB), coke-based artificial graphite, and pitch-based artificial graphite. As artificial graphite, spherical graphite having a spherical shape can be used. For example, MCMB is preferably used because it may have a spherical shape. Moreover, MCMB may preferably be used because it can relatively easily have a small surface area. Examples of natural graphite include flake graphite and spherical natural graphite.

Graphite has a low potential substantially equal to that of lithium metal (higher than or equal to 0.05 V and lower than or equal to 0.3 V vs. Li/Li⁺ when lithium ions are inserted into graphite (while a lithium-graphite intercalation compound is formed). For this reason, a lithium-ion battery using graphite can have a high operating voltage. In addition, graphite is preferred because of its advantages such as a relatively high capacity per unit volume, relatively small volume expansion, low cost, and a higher level of safety than that of lithium metal.

Non-graphitizing carbon can be obtained by baking a synthetic resin such as a phenol resin, and an organic substance of plant origin, for example. In non-graphitizing carbon contained in the negative electrode active material of the lithium-ion battery of one embodiment of the present invention, the interplanar spacing of a (002) plane, which is measured by X-ray diffraction (XRD), is preferably greater than or equal to 0.34 nm and less than or equal to 0.50 nm, further preferably greater than or equal to 0.35 nm and less than or equal to 0.42 nm.

As the negative electrode active material, an element that enables charge and discharge reactions by an alloying reaction and a dealloying reaction with lithium can be used. For example, a material containing at least one of silicon, tin, gallium, aluminum, germanium, lead, antimony, bismuth, silver, zinc, cadmium, indium, and the like can be used. Such elements have a higher capacity than carbon. In particular, silicon has a high theoretical capacity of 4200 mAh/g. For this reason, silicon is preferably used as the negative electrode active material. Alternatively, a compound containing any of the above elements may be used. Examples of the compound include SiO, Mg₂Si, Mg₂Ge, SnO, SnO₂, Mg₂Sn, SnS₂, V₂Sn₃, FeSn₂, CoSn₂, Ni₃Sn₂, Cu₆Sn₅, Ag₃Sn, Ag₃Sb, Ni₂MnSb, CeSb₃, LaSn₃, La₃Co₂Sn₇, CoSb₃, InSb, and SbSn. Here, an element that enables charge and discharge reactions by alloying and dealloying reactions with lithium and a compound containing the element, for example, are referred to as alloy-based materials in some cases.

In this specification and the like, “SiO” refers, for example, to silicon monoxide. SiO can alternatively be expressed as SiOₓ. Here, it is preferable that x be 1 or have an approximate value of 1. For example, x is preferably greater than or equal to 0.2 and less than or equal to 1.5, further preferably greater than or equal to 0.3 and less than or equal to 1.2.

As the negative electrode active material, an oxide such as titanium dioxide (TiO₂), lithium titanium oxide (Li₄Ti₅O₁₂), a lithium-graphite intercalation compound (LiₓC₆), niobium pentoxide (Nb₂O₅), tungsten oxide (WO₂), or molybdenum oxide (MoO₂) can be used.

Alternatively, as the negative electrode active material, Li₃₋ₓMₓN (M=Co, Ni, or Cu) with a Li₃N structure, which is a composite nitride of lithium and a transition metal, can be used. For example, Li_{2.6}Co_{0.4}N₃ is preferable because of its high discharge capacity (900 mAh/g and 1890 mAh/cm³).

A composite nitride of lithium and a transition metal is preferably used, in which case lithium ions are contained in the negative electrode active material and thus the negative electrode active material can be used in combination with a positive electrode active material that does not contain lithium ions, such as V₂O₅ or Cr₃O₈. Note that in the case of using a material containing lithium ions as a positive electrode active material, the composite nitride of lithium and a transition metal can be used as the negative electrode active material by extracting the lithium ions contained in the positive electrode active material in advance.

A material that causes a conversion reaction can be used as the negative electrode active material. For example, a transition metal oxide that does not form an alloy with lithium, such as cobalt oxide (CoO), nickel oxide (NiO), or iron oxide (FeO), may be used as the negative electrode active material. Other examples of the material that causes a conversion reaction include oxides such as Fe₂O₃, CuO, Cu₂O, RuO₂, and Cr₂O₃, sulfides such as CoS_{0.89}, NiS, and CuS, nitrides such as Zn₃N₂, Cu₃N, and Ge₃N₄, phosphides such as NiP₂, FeP₂, and CoP₃, and fluorides such as FeF₃ and BiF₃.

Note that one kind of negative electrode active material among the negative electrode active materials shown above can be used; alternatively, a plurality of kinds can be used in combination. For example, a combination of a carbon material and silicon or a combination of a carbon material and silicon monoxide can be used.

As another mode of the negative electrode, a negative electrode that does not contain a negative electrode active material at the completion of the fabrication of the battery may be used. As the negative electrode that does not contain a negative electrode active material, for example, a negative electrode can be used in which only a negative electrode current collector is included at the completion of the fabrication of the battery and in which lithium ions extracted from the positive electrode active material due to charging of the battery are deposited as lithium metal over the negative electrode current collector and form the negative electrode active material layer. A battery including such a negative electrode is referred to as a negative electrode-free (anode-free) battery, a negative electrodeless (anodeless) battery, or the like in some cases.

In the case where the negative electrode that does not contain a negative electrode active material is used, a film for making lithium deposition uniform may be provided over the negative electrode current collector. For the film for making lithium deposition uniform, for example, a solid electrolyte having lithium ion conductivity can be used. As the solid electrolyte, a sulfide-based solid electrolyte, an oxide-based solid electrolyte, a polymer-based solid electrolyte, or the like can be used. In particular, the polymer-based solid electrolyte can be uniformly formed as a film over the negative electrode current collector relatively easily, and thus is suitable for the film for making lithium deposition uniform. As another film for making lithium deposition uniform, for example, a metal film that forms an alloy with lithium can be used. As the metal film that forms an alloy with lithium, for example, a magnesium metal film can be used. It is suitable for the film for making lithium deposition uniform because lithium and magnesium form a solid solution in a wide range of compositions.

In the case where the negative electrode that does not contain a negative electrode active material is used, a negative electrode current collector having projections and depressions can be used. In the case where the negative electrode current collector having projections and depressions is used, a depression of the negative electrode current collector becomes a cavity in which lithium contained in the negative electrode current collector is easily deposited, so that the lithium can be inhibited from having a dendrite-like shape when being deposited.

### Binder

As the binder, a rubber material such as styrene-butadiene rubber (SBR), styrene-isoprene-styrene rubber, acrylonitrile-butadiene rubber, butadiene rubber, or ethylene-propylene-diene copolymer is preferably used, for example. Fluororubber can also be used as the binder.

As the binder, for example, a water-soluble polymer is preferably used. As the water-soluble polymer, a polysaccharide can be used, for example. As the polysaccharide, starch, a cellulose derivative such as carboxymethyl cellulose (CMC), methyl cellulose, ethyl cellulose, hydroxypropyl cellulose, diacetyl cellulose, or regenerated cellulose, or the like can be used. It is further preferable that such a water-soluble polymer be used in combination with any of the above rubber materials.

Alternatively, as the binder, a material such as polystyrene, poly(methyl acrylate), poly(methyl methacrylate) (PMMA), sodium polyacrylate, polyvinyl alcohol (PVA), polyethylene oxide (PEO), polypropylene oxide, polyimide, polyvinyl chloride, polytetrafluoroethylene, polyethylene, polypropylene, polyisobutylene, polyethylene terephthalate, nylon, polyvinylidene fluoride (PVDF), polyacrylonitrile (PAN), ethylene-propylene-diene polymer, polyvinyl acetate, or nitrocellulose is preferably used.

A plurality of the above-described materials may be used in combination for the binder.

For example, a material having a significant viscosity modifying effect and another material may be used in combination. For example, a rubber material or the like has high adhesion and high elasticity but may have difficulty in viscosity modification when mixed in a solvent. In such a case, a rubber material or the like is preferably mixed with a material having a significant viscosity modifying effect, for example. As a material having a significant viscosity modifying effect, for instance, a water-soluble polymer is preferably used. As a water-soluble polymer having a significant viscosity modifying effect, the above-mentioned polysaccharide, for instance, a cellulose derivative such as carboxymethyl cellulose (CMC), methyl cellulose, ethyl cellulose, hydroxypropyl cellulose, diacetyl cellulose, or regenerated cellulose, starch, or the like can be used.

Note that a cellulose derivative such as carboxymethyl cellulose obtains a higher solubility when converted into a salt such as a sodium salt or an ammonium salt of carboxymethyl cellulose, and thus easily exerts an effect as a viscosity modifier. A high solubility can also increase the dispersibility of an active material or other components in the fabrication of slurry for an electrode. In this specification and the like, cellulose and a cellulose derivative used as a binder of an electrode include salts thereof.

A water-soluble polymer stabilizes the viscosity by being dissolved in water and allows stable dispersion of the active material and another material combined as a binder, such as styrene-butadiene rubber, in an aqueous solution. Furthermore, a water-soluble polymer is expected to be easily and stably adsorbed onto an active material surface because it has a functional group. Many cellulose derivatives, such as carboxymethyl cellulose, have a functional group such as a hydroxyl group or a carboxyl group. Because of functional groups, polymers are expected to interact with each other and cover an active material surface in a large area.

In the case where the binder that covers or is in contact with the active material surface forms a film, the film is expected to serve also as a passivation film to suppress the decomposition of the electrolyte solution. Here, the “passivation film” refers to a film without electrical conductivity or a film with extremely low electrical conductivity, and can inhibit the decomposition of the electrolyte solution at a potential at which a battery reaction occurs when the passivation film is formed on the active material surface, for example. It is further desirable that the passivation film can conduct lithium ions while inhibiting electrical conduction.

### Conductive Material

The conductive material is also referred to as a conductivity-imparting agent or a conductive additive, and a carbon material is used as the conductive material. The conductive material is attached between a plurality of active materials, whereby the plurality of active materials are electrically connected to each other, and the conductivity increases. Note that the term “attach” refers not only to a state where an active material and a conductive material are physically in close contact with each other, and includes, for example, the following concepts: the case where covalent bonding occurs, the case where bonding with the Van der Waals force occurs, the case where a conductive material covers part of the surface of an active material, the case where a conductive material is embedded in surface roughness of an active material, and the case where an active material and a conductive material are electrically connected to each other without being in contact with each other.

Active material layers such as the positive electrode active material layer and the negative electrode active material layer preferably contain a conductive material.

For example, one kind or two or more kinds of carbon black such as acetylene black and furnace black, graphite such as artificial graphite and natural graphite, carbon fiber such as carbon nanofiber and carbon nanotube, and a graphene compound can be used as the conductive material.

As the carbon fiber, carbon fiber such as mesophase pitch-based carbon fiber or isotropic pitch-based carbon fiber can be used, for example. As the carbon fiber, carbon nanofiber, carbon nanotube, or the like can also be used. Carbon nanotube can be fabricated by, for example, a vapor deposition method.

A graphene compound in this specification and the like refers to graphene, multilayer graphene, multi graphene, graphene oxide, multilayer graphene oxide, multi graphene oxide, reduced graphene oxide, reduced multilayer graphene oxide, reduced multi graphene oxide, graphene quantum dots, and the like. A graphene compound contains carbon, has a plate-like shape, a sheet-like shape, or the like, and has a two-dimensional structure formed of a six-membered ring composed of carbon atoms. The two-dimensional structure formed of the six-membered ring composed of carbon atoms may be referred to as a carbon sheet. A graphene compound may include a functional group. The graphene compound is preferably bent. The graphene compound may be rounded like carbon nanofiber.

The active material layer may contain, as a conductive material, metal powder or metal fiber of copper, nickel, aluminum, silver, gold, or the like, a conductive ceramic material, or the like.

The content of the conductive material to the total volume of the active material layer is preferably greater than or equal to 1 wt % and less than or equal to 10 wt %, further preferably greater than or equal to 1 wt % and less than or equal to 5 wt %.

Unlike a particulate conductive material such as carbon black, which makes point contact with an active material, the graphene compound is capable of making low-resistance surface contact; accordingly, the electrical conduction between the particulate active material and the graphene compound can be improved with a smaller amount of the graphene compound than that of a normal conductive material. This can increase the proportion of the active material in the active material layer. Accordingly, the discharge capacity of the battery can be increased.

A particulate carbon-containing compound such as carbon black or graphite and a fibrous carbon-containing compound such as carbon nanotube easily enter a microscopic space. A microscopic space means, for example, a region or the like between a plurality of active materials. When a carbon-containing compound that easily enters a microscopic space and a sheet-like carbon-containing compound, such as graphene, that can impart conductivity to a plurality of particles are used in combination, the density of the electrode is increased and an excellent conductive path can be formed. The battery obtained by the fabrication method of one embodiment of the present invention can have high capacity density per volume and stability, and is effective as an in-vehicle battery.

### Current Collector

As the current collector, a highly conductive material which does not alloy with a carrier ion of lithium or the like, for example, a metal such as stainless steel, gold, platinum, zinc, iron, copper, aluminum, or titanium, or an alloy thereof can be used. The current collector can have a sheet-like shape, a net-like shape, a punching-metal shape, an expanded-metal shape, or the like as appropriate.

A resin current collector can be used as the current collector. As the resin current collector, for example, a resin current collector including a resin such as polyolefin (e.g., polypropylene or polyethylene), nylon (polyamide), polyimide, vinylon, polyester, acrylic, or polyurethane, and a particulate or fibrous conductive material (also referred to as a conductive filler) can be used.

As the conductive material contained in the resin current collector, a conductive carbon material and one or more of metal materials such as aluminum, titanium, stainless steel, gold, platinum, zinc, iron, and copper can be used. For example, one kind or two or more kinds of carbon black such as acetylene black or furnace black, graphite such as artificial graphite or natural graphite, carbon fiber such as carbon nanofiber or carbon nanotube, graphene, and a graphene compound can be used as the conductive carbon material. Note that in the case where the resin current collector is used as a positive electrode current collector, an antioxidant such as a hindered phenol-based material is further preferably used.

As the carbon fiber, carbon fiber such as mesophase pitch-based carbon fiber or isotropic pitch-based carbon fiber can be used, for example. As the carbon fiber, carbon nanofiber, carbon nanotube, or the like can also be used. Carbon nanotube can be fabricated by, for example, a vapor deposition method.

Note that the average particle diameter of the conductive material contained in the resin current collector can be greater than or equal to 10 nm and less than or equal to 10 μm, and is preferably greater than or equal to 30 nm and less than or equal to 5 μm.

The current collector preferably has a thickness greater than or equal to 5 μm and less than or equal to 30 μm.

Note that a material that does not alloy with carrier ions of lithium or the like is preferably used for the negative electrode current collector.

### Positive Electrode

A positive electrode includes a positive electrode active material layer and a positive electrode current collector. The positive electrode active material layer includes a positive electrode active material and may further include at least one of a conductive material and a binder. Note that the positive electrode current collector, the conductive material, and the binder described in [Negative electrode] can be used.

Metal foil can be used as the current collector, for example. The positive electrode can be formed by applying slurry onto the metal foil and drying the slurry. Note that pressing may be performed after drying. The positive electrode is a component obtained by forming an active material layer over the current collector.

Slurry refers to a material solution that is used to form the active material layer over the current collector and includes an active material, a binder, and a solvent, preferably also a conductive material mixed therewith. Slurry may also be referred to as slurry for an electrode or active material slurry; in some cases, slurry for forming a positive electrode active material layer is referred to as slurry for a positive electrode.

### Positive Electrode Active Material

As the positive electrode active material, one or more of a composite oxide having a layered rock-salt structure, a composite oxide having an olivine structure, and a composite oxide having a spinel structure can be used.

As the composite oxide having a layered rock-salt structure, one or more of lithium cobalt oxide, lithium nickel-cobalt-manganese oxide, lithium nickel-cobalt-aluminum oxide, and lithium nickel-manganese-aluminum oxide can be used. Note that the composition formula can be represented by LiM1O₂ (M1 is one or more selected from nickel, cobalt, manganese, and aluminum), and a coefficient of the composition formula is not limited to an integer.

As the lithium cobalt oxide, for example, lithium cobalt oxide to which magnesium and fluorine are added can be used. It is preferable to use lithium cobalt oxide to which magnesium, fluorine, aluminum, and nickel are added.

As the lithium nickel-cobalt-manganese oxide, for example, lithium nickel-cobalt-manganese oxide with a ratio such as nickel:cobalt:manganese=1:1:1, 6:2:2, 8:1:1, or 9:0.5:0.5 can be used. As the above-described lithium nickel-cobalt-manganese oxide, for example, lithium nickel-cobalt-manganese oxide to which one or more of aluminum, calcium, barium, strontium, and gallium are added is preferably used.

As the composite oxide having an olivine structure, one or more of lithium iron phosphate, lithium manganese phosphate, lithium cobalt phosphate, and lithium iron manganese phosphate can be used. Note that the composition formula can be represented by LiM2PO₄ (M2 is one or more selected from iron, manganese, and cobalt), and a coefficient of the composition formula is not limited to an integer.

Furthermore, composite oxide having a spinel structure, such as LiMn₂O₄, can be used.

### Electrolyte

Examples of the electrolyte are described below. As one mode of the electrolyte, a liquid electrolyte (also referred to as an electrolyte solution) containing a solvent and an electrolyte dissolved in the solvent can be used. The electrolyte is not limited to a liquid electrolyte (electrolyte solution) that is liquid at room temperature, and a solid electrolyte can be used as well. Alternatively, an electrolyte including both a liquid electrolyte that is liquid at room temperature and a solid electrolyte that is a solid at room temperature (such an electrolyte is referred to as a semi-solid electrolyte) can also be used. Note that when the solid electrolyte or the semi-solid electrolyte is used for a bendable battery, employing a structure where part of a stack in the battery includes the electrolyte can maintain the flexibility of the battery.

In the case where a liquid electrolyte is used for a secondary battery, one of ethylene carbonate (EC), propylene carbonate (PC), butylene carbonate, chloroethylene carbonate, vinylene carbonate, γ-butyrolactone, γ-valerolactone, dimethyl carbonate (DMC), diethyl carbonate (DEC), ethyl methyl carbonate (EMC), methyl formate, methyl acetate, ethyl acetate, methyl propionate, ethyl propionate, propyl propionate, methyl butyrate, 1,3-dioxane, 1,4-dioxane, dimethoxyethane (DME), dimethyl sulfoxide, diethyl ether, methyl diglyme, acetonitrile, benzonitrile, tetrahydrofuran, sulfolane, and sultone can be used, or two or more kinds thereof can be used in an appropriate combination at an appropriate ratio, for example.

Alternatively, the use of one or more of ionic liquids (normal temperature molten salts) which have features of non-flammability and non-volatility as a solvent of an electrolyte can prevent a secondary battery from exploding or catching fire even when an internal region of a secondary battery shorts out or the temperature in the internal region increases owing to overcharging or the like. An ionic liquid contains a cation and an anion, specifically, an organic cation and an anion. Examples of the organic cation include aliphatic onium cations such as a quaternary ammonium cation, a tertiary sulfonium cation, and a quaternary phosphonium cation, and aromatic cations such as an imidazolium cation and a pyridinium cation. Examples of the anion include a monovalent amide-based anion, a monovalent methide-based anion, a fluorosulfonate anion, a perfluoroalkylsulfonate anion, a tetrafluoroborate anion, a perfluoroalkylborate anion, a hexafluorophosphate anion, and a perfluoroalkylphosphate anion.

The secondary battery of one embodiment of the present invention includes, as a carrier ion, an alkali metal ion such as a lithium ion, a sodium ion, or a potassium ion or an alkaline earth metal ion such as a calcium ion, a strontium ion, a barium ion, a beryllium ion, or a magnesium ion, for example.

In the case where lithium ions are used as carrier ions, the electrolyte contains lithium salt, for example. As the lithium salt, LiPF₆, LiClO₄, LiAsF₆, LiBF₄, LiAlCl₄, LiSCN, LiBr, LiI, Li₂SO₄, Li₂B₁₀Cl₁₀, Li₂B₁₂Cl₁₂, LiCF₃SO₃, LiC₄F₉SO₃, LiC(CF₃SO₂)₃, LiC(C₂F₅SO₂)₃, LiN(CF₃SO₂)₂, LiN(C₄F₉SO₂) (CF₃SO₂), LiN(C₂F₅SO₂)₂, or the like can be used, for example.

For example, an organic solvent described in this embodiment contains ethylene carbonate (EC), ethyl methyl carbonate (EMC), and dimethyl carbonate (DMC). When the total content of the ethylene carbonate, the ethyl methyl carbonate, and the dimethyl carbonate is set to 100 vol %, an organic solvent in which the volume ratio between the ethylene carbonate, the ethyl methyl carbonate, and the dimethyl carbonate is x:y:100−x−y (where 5≤x≤35 and 0<y<65) can be used. More specifically, an organic solvent containing EC, EMC, and DMC at EC:EMC:DMC=30:35:35 (volume ratio) can be used.

The electrolyte solution is preferably highly purified and contains a small amount of dust particles and elements other than the constituent elements of the electrolyte solution (hereinafter, also simply referred to as “impurities”). Specifically, the weight ratio of impurities to the electrolyte solution is preferably less than or equal to 1%, further preferably less than or equal to 0.1%, still further preferably less than or equal to 0.01%.

In order to form a coating film (Solid Electrolyte Interphase) at the interface between an electrode (active material layer) and the electrolyte solution for the purpose of improvement of the safety or the like, an additive agent such as vinylene carbonate (VC), propane sultone (PS), tert-butylbenzene (TBB), fluoroethylene carbonate (FEC), lithium bis(oxalate)borate (LiBOB), or a dinitrile compound such as succinonitrile or adiponitrile may be added to the electrolyte solution. The concentration of the additive agent in the solvent is, for example, higher than or equal to 0.1 wt % and lower than or equal to 5 wt %.

When a high-molecular material that can gel is contained in the electrolyte, safety against liquid leakage and the like is improved. Typical examples of the gelled high-molecular material include a silicone gel, an acrylic gel, an acrylonitrile gel, a polyethylene oxide-based gel, a polypropylene oxide-based gel, and a gel of a fluorine-based polymer.

As the high-molecular material, for example, a polymer having a polyalkylene oxide structure, such as polyethylene oxide (PEO); PVDF; polyacrylonitrile; a copolymer containing any of them; or the like can be used. For example, PVDF-HFP, which is a copolymer of PVDF and hexafluoropropylene (HFP), can be used. The formed polymer may be porous.

### Separator

When the electrolyte includes an electrolyte solution, a separator is placed between the positive electrode and the negative electrode. As the separator, for example, a fiber containing cellulose such as paper; nonwoven fabric; a glass fiber; ceramics; a synthetic fiber using nylon (polyamide), vinylon (polyvinyl alcohol-based fiber), polyester, acrylic, polyolefin, or polyurethane; or the like can be used. The separator is preferably processed into a bag-like shape to wrap one of the positive electrode and the negative electrode.

The separator may have a multilayer structure. For example, an organic material film of polypropylene, polyethylene, or the like can be coated with a ceramics-based material, a fluorine-based material, a polyamide-based material, a mixture thereof, or the like. Examples of the ceramics-based material include aluminum oxide particles and silicon oxide particles. Examples of the fluorine-based material include PVDF and polytetrafluoroethylene. Examples of the polyamide-based material include nylon and aramid (meta-based aramid and para-based aramid).

When the separator is coated with the ceramics-based material, the oxidation resistance is improved; hence, degradation of the separator during high-voltage charging can be inhibited and thus the reliability of the secondary battery can be improved. When the separator is coated with the fluorine-based material, the separator is easily brought into close contact with an electrode, resulting in high output characteristics. When the separator is coated with the polyamide-based material, in particular, aramid, heat resistance can be improved to improve the safety of the secondary battery.

For example, both surfaces of a polypropylene film may be coated with a mixed material of aluminum oxide and aramid. Alternatively, a surface of a polypropylene film that is in contact with the positive electrode may be coated with a mixed material of aluminum oxide and aramid, and a surface of the polypropylene film that is in contact with the negative electrode may be coated with the fluorine-based material.

With the use of a separator having a multilayer structure, the capacity per volume of the secondary battery can be increased because the safety of the secondary battery can be maintained even when the total thickness of the separator is small.

### Exterior Body

For an exterior body included in the secondary battery, a metal material such as aluminum or a resin material can be used, for example. A film-like exterior body can also be used. As the film, for example, it is possible to use a film having a three-layer structure in which a highly flexible metal thin film of aluminum, stainless steel, copper, nickel, or the like is provided over a film formed of a material such as polyethylene, polypropylene, polycarbonate, ionomer, or polyamide, and an insulating synthetic resin film of a polyamide-based resin, a polyester-based resin, or the like is provided over the metal thin film as the outer surface of the exterior body.

The structure, method, and the like described in this embodiment can be used in an appropriate combination with structures, methods, and the like described in the other embodiments.

### Embodiment 3

In this embodiment, examples of the shape of the battery 10 will be described.

### Coin-Type Secondary Battery

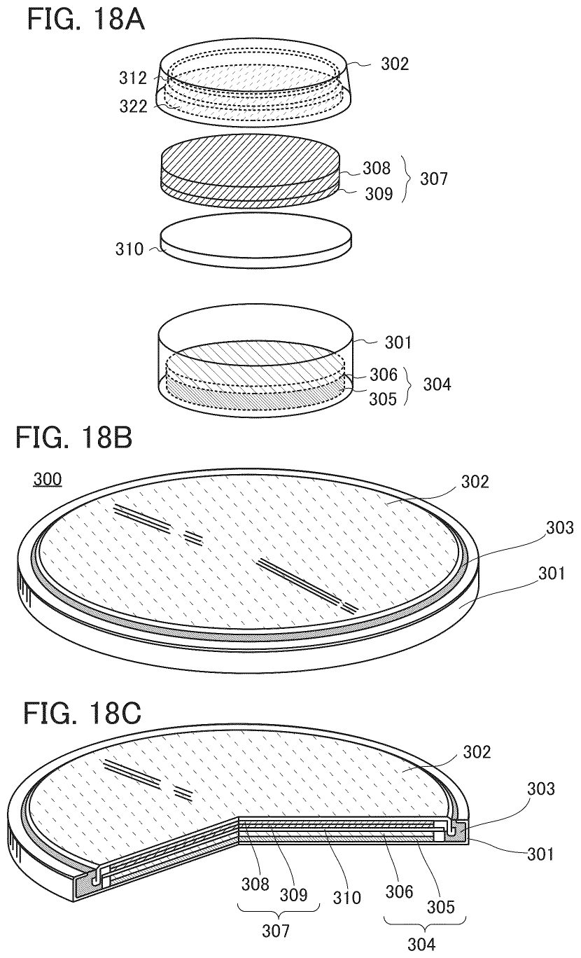

An example of a coin-type secondary battery is described here. FIG. 18A is an exploded perspective view of a coin-type (single-layer flat type) secondary battery, FIG. 18B is an external view thereof, and FIG. 18C is a cross-sectional view thereof. Coin-type secondary batteries are mainly used in small electronic devices.

Note that, for easy understanding, FIG. 18A is a schematic view illustrating overlap (a vertical relation and a positional relation) between components. Thus, FIG. 18A and FIG. 18B do not completely correspond with each other.

In FIG. 18A, a positive electrode 304, a separator 310, a negative electrode 307, a spacer 322, and a washer 312 are overlaid. They are sealed with a negative electrode can 302, a positive electrode can 301, and a gasket. Note that the gasket for sealing is not illustrated in FIG. 18A. The spacer 322 and the washer 312 are used to protect the inside or fix the position inside the cans at the time when the positive electrode can 301 and the negative electrode can 302 are bonded with pressure. For the spacer 322 and the washer 312, stainless steel or an insulating material is used.

The positive electrode 304 has a stacked-layer structure in which a positive electrode active material layer 306 is formed over a positive electrode current collector 305.

FIG. 18B is a perspective view of a completed coin-type secondary battery.

In a coin-type secondary battery 300, the positive electrode can 301 doubling as a positive electrode terminal and the negative electrode can 302 doubling as a negative electrode terminal are insulated from each other and sealed by a gasket 303 made of polypropylene or the like. The positive electrode 304 includes the positive electrode current collector 305 and the positive electrode active material layer 306 provided in contact with the positive electrode current collector 305. The negative electrode 307 includes a negative electrode current collector 308 and a negative electrode active material layer 309 provided in contact with the negative electrode current collector 308. The negative electrode 307 is not limited to having a stacked-layer structure, and lithium metal foil or lithium-aluminum alloy foil may be used.

Note that only one surface of each of the positive electrode 304 and the negative electrode 307 used for the coin-type secondary battery 300 is provided with an active material layer.

For the positive electrode can 301 and the negative electrode can 302, a metal having corrosion resistance to an electrolyte solution, such as nickel, aluminum, or titanium, an alloy of such a metal, or an alloy of such a metal and another metal (e.g., stainless steel) can be used. The positive electrode can 301 and the negative electrode can 302 are preferably covered with nickel, aluminum, or the like in order to prevent corrosion due to the electrolyte solution or the like. The positive electrode can 301 and the negative electrode can 302 are electrically connected to the positive electrode 304 and the negative electrode 307, respectively.

The negative electrode 307, the positive electrode 304, and the separator 310 are immersed in the electrolyte solution. Then, as illustrated in FIG. 18C, the positive electrode 304, the separator 310, the negative electrode 307, and the negative electrode can 302 are stacked in this order with the positive electrode can 301 positioned at the bottom, and the positive electrode can 301 and the negative electrode can 302 are bonded with pressure with the gasket 303 therebetween. In this manner, the coin-type secondary battery 300 is manufactured. In the coin-type secondary battery 300, the positive electrode can 301 and the negative electrode can 302 can be referred to as a positive electrode terminal and a negative electrode terminal, respectively.

With the above-described structure, the coin-type secondary battery 300 can have high discharge capacity and excellent cycle performance.

### Cylindrical Secondary Battery

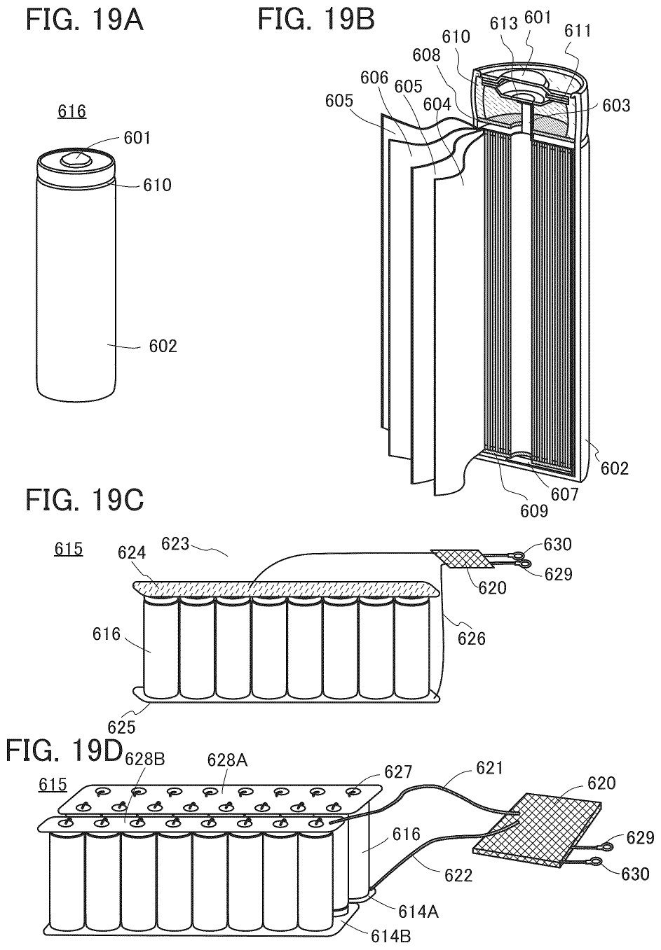

An example of a cylindrical secondary battery is described with reference to FIG. 19A. As illustrated in FIG. 19A, a cylindrical secondary battery 616 includes a positive electrode cap (battery cap) 601 on the top surface and a battery can (outer can) 602 on the side surface and bottom surface. The positive electrode cap 601 and the battery can (outer can) 602 are insulated from each other by a gasket (insulating gasket) 610. In the cylindrical secondary battery 616, the positive electrode cap 601 and the battery can 602 can be referred to as a positive electrode terminal and a negative electrode terminal, respectively.

FIG. 19B schematically illustrates a cross section of the cylindrical secondary battery. The cylindrical secondary battery illustrated in FIG. 19B includes the positive electrode cap (battery cap) 601 on the top surface and the battery can (outer can) 602 on the side surface and bottom surface. The positive electrode cap and the battery can (outer can) 602 are insulated from each other by the gasket (insulating gasket) 610.

Inside the battery can 602 having a hollow cylindrical shape, a battery element in which a strip-like positive electrode 604 and a strip-like negative electrode 606 are wound with a separator 605 located therebetween is provided. Although not illustrated, the battery element is wound around a central axis. One end of the battery can 602 is closed and the other end thereof is opened. For the battery can 602, a metal having corrosion resistance to an electrolyte solution, such as nickel, aluminum, or titanium, an alloy of such a metal, or an alloy of such a metal and another metal (e.g., stainless steel) can be used. The battery can 602 is preferably covered with nickel, aluminum, or the like in order to prevent corrosion due to the electrolyte solution. Inside the battery can 602, the battery element in which the positive electrode, the negative electrode, and the separator are wound is provided between a set of an insulating plate 608 and an insulating plate 609 that face each other. The inside of the battery can 602 provided with the battery element is filled with a nonaqueous electrolyte solution (not illustrated). As the nonaqueous electrolyte solution, a nonaqueous electrolyte solution that is similar to that of the coin-type secondary battery can be used.

Since a positive electrode and a negative electrode that are used for a cylindrical storage battery are wound, active materials are preferably formed on both surfaces of a current collector.

A positive electrode terminal (positive electrode current collecting lead) 603 is connected to the positive electrode 604, and a negative electrode terminal (negative electrode current collecting lead) 607 is connected to the negative electrode 606. Both the positive electrode terminal 603 and the negative electrode terminal 607 can be formed using a metal material such as aluminum. The positive electrode terminal 603 and the negative electrode terminal 607 are resistance-welded to a safety valve mechanism 613 and the bottom of the battery can 602, respectively. The safety valve mechanism 613 is electrically connected to the positive electrode cap 601 through a PTC element (Positive Temperature Coefficient) 611. The safety valve mechanism 613 cuts off electrical connection between the positive electrode cap 601 and the positive electrode 604 when the internal pressure of the battery exceeds a predetermined threshold. The PTC element 611, which is a thermally sensitive resistor whose resistance increases as temperature rises, limits the amount of current by increasing the resistance, in order to prevent abnormal heat generation. Barium titanate (BaTiO₃)-based semiconductor ceramic or the like can be used for the PTC element.

FIG. 19C illustrates an example of a power storage module 615. The power storage module 615 includes a plurality of secondary batteries 616. Positive electrodes of the secondary batteries are in contact with and electrically connected to a conductor 624. Negative electrodes of the secondary batteries are in contact with and electrically connected to a conductor 625. Thus, the conductor 624 can be referred to as a positive electrode terminal of a power storage device (an assembled battery), and the conductor 625 can be referred to as a negative electrode terminal of the power storage device (the assembled battery). The conductor 624 is electrically connected to a control circuit 620 through a wiring 623. The conductor 625 is electrically connected to the control circuit 620 through a wiring 626. As the control circuit 620, a charging and discharging control circuit for performing charging, discharging, and the like or a protection circuit for preventing overcharging and/or overdischarging can be used. The control circuit 620 includes an external terminal 629 and an external terminal 630.

FIG. 19D illustrates an example of the power storage module 615. The power storage module 615 includes the plurality of secondary batteries 616, and the plurality of secondary batteries 616 are sandwiched between a conductive plate 628 (a conductive plate 628A and a conductive plate 628B) and a conductive plate 614 (a conductive plate 614A and a conductive plate 614B). The plurality of secondary batteries 616 are electrically connected to the conductive plate 628 and the conductive plate 614 through a wiring 627. The plurality of secondary batteries 616 may be connected in parallel, connected in series, or connected in series after being connected in parallel. With the power storage module 615 including the plurality of secondary batteries 616, large electric power can be extracted. Note that the plurality of secondary batteries 616 can be referred to as a power storage device or an assembled battery. In this case, a conductive plate having the highest potential between the conductive plate 628 and the conductive plate 614 can be referred to as a positive electrode terminal of the power storage device or a positive electrode terminal of the assembled battery. A conductive plate having the lowest potential between the conductive plate 628 and the conductive plate 614 can be referred to as a negative electrode terminal of the power storage device or a negative electrode terminal of the assembled battery.

A temperature control device may be provided between the plurality of secondary batteries 616. The secondary batteries 616 can be cooled with the temperature control device when overheated, whereas the secondary batteries 616 can be heated with the temperature control device when cooled too much. Thus, the performance of the power storage module 615 is less likely to be influenced by the outside temperature.

In FIG. 19D, the power storage module 615 is electrically connected to the control circuit 620 through a wiring 621 and a wiring 622. The wiring 621 is electrically connected to the positive electrodes of the plurality of secondary batteries 616 through the conductive plate 628, and the wiring 622 is electrically connected to the negative electrodes of the plurality of secondary batteries 616 through the conductive plate 614. The control circuit 620 includes an external terminal 629 and an external terminal 630.

### Other Structure Examples of Secondary Battery

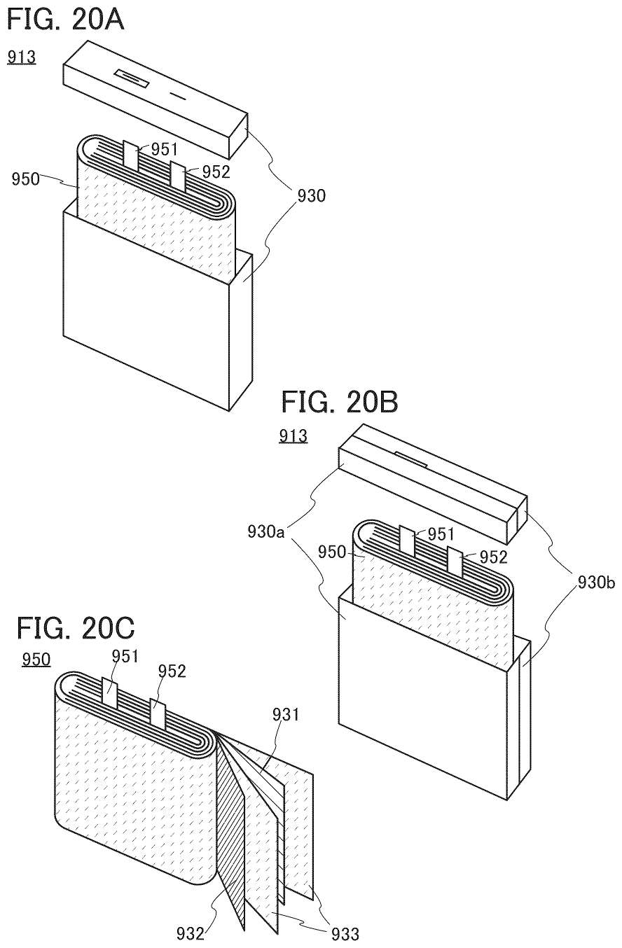

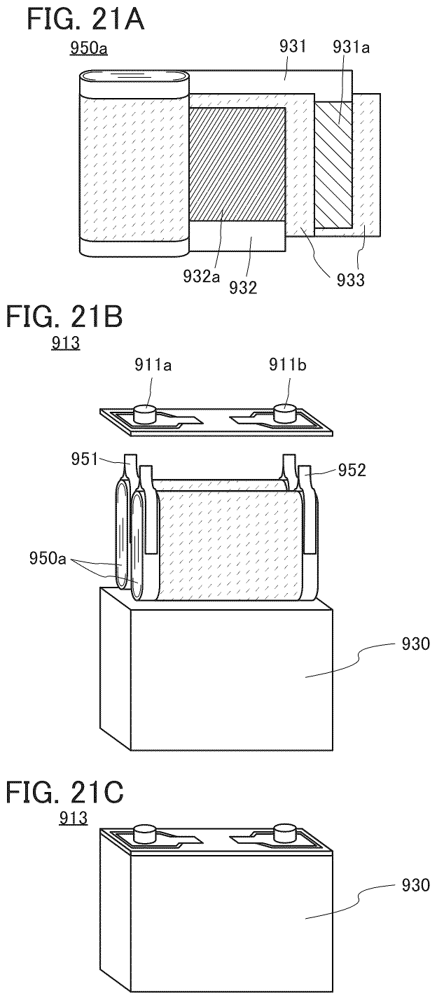

Structure examples of secondary batteries are described with reference to FIG. 20 and FIG. 21.

A secondary battery 913 illustrated in FIG. 20A includes a wound body 950 provided with a terminal 951 and a terminal 952 inside a housing 930. The wound body 950 is immersed in an electrolyte solution inside the housing 930. The terminal 952 is in contact with the housing 930. The terminal 951 is not in contact with the housing 930 with use of an insulator or the like. Note that in FIG. 20A, the housing 930 divided into pieces is illustrated for convenience; however, in the actual structure, the wound body 950 is covered with the housing 930, and the terminal 951 and the terminal 952 extend to the outside of the housing 930. For the housing 930, a metal material (e.g., aluminum) or a resin material can be used.

Note that as illustrated in FIG. 20B, the housing 930 illustrated in FIG. 20A may be formed using a plurality of materials. For example, in the secondary battery 913 illustrated in FIG. 20B, a housing 930a and a housing 930b are attached to each other, and the wound body 950 is provided in a region surrounded by the housing 930a and the housing 930b.

For the housing 930a, an insulating material such as an organic resin can be used. In particular, when a material such as an organic resin is used for the side on which an antenna is formed, blocking of an electric field by the secondary battery 913 can be inhibited. When an electric field is not significantly blocked by the housing 930a, an antenna may be provided inside the housing 930a. For the housing 930b, a metal material can be used, for example.

FIG. 20C illustrates the structure of the wound body 950. The wound body 950 includes a negative electrode 931, a positive electrode 932, and separators 933. The wound body 950 is obtained by winding a sheet of a stack in which the negative electrode 931 and the positive electrode 932 overlap with each other with the separator 933 therebetween. Note that a plurality of stacks each including the negative electrode 931, the positive electrode 932, and the separators 933 may be further stacked.

As illustrated in FIG. 21, the secondary battery 913 may include a wound body 950a. The wound body 950a illustrated in FIG. 21A includes the negative electrode 931, the positive electrode 932, and the separators 933. The negative electrode 931 includes a negative electrode active material layer 931a. The positive electrode 932 includes a positive electrode active material layer 932a.

The separator 933 has a larger width than the negative electrode active material layer 931a and the positive electrode active material layer 932a, and is wound to overlap with the negative electrode active material layer 931a and the positive electrode active material layer 932a. In terms of safety, the width of the negative electrode active material layer 931a is preferably larger than that of the positive electrode active material layer 932a. The wound body 950a having such a shape is preferable because of its high level of safety and high productivity.

As illustrated in FIG. 21B, the negative electrode 931 is electrically connected to a terminal 951 by ultrasonic bonding, welding, or pressure bonding. The terminal 951 is electrically connected to a terminal 911a. The positive electrode 932 is electrically connected to a terminal 952 by ultrasonic bonding, welding, or pressure bonding. The terminal 952 is electrically connected to a terminal 911b.

As illustrated in FIG. 21C, the wound body 950a and an electrolyte solution are covered with the housing 930, whereby the secondary battery 913 is completed. The housing 930 is preferably provided with a safety valve, an overcurrent protection element, and the like. In order to prevent the battery from exploding, the safety valve is a valve to be released when the internal pressure of the housing 930 reaches a predetermined pressure.

As illustrated in FIG. 21B, the secondary battery 913 may include a plurality of the wound bodies 950a. The use of the plurality of wound bodies 950a enables the secondary battery 913 to have higher discharge capacity. The description of the secondary battery 913 illustrated in FIG. 20A to FIG. 20C can be referred to for the other components of the secondary battery 913 illustrated in FIG. 21A and FIG. 21B.

### Laminated Secondary Battery

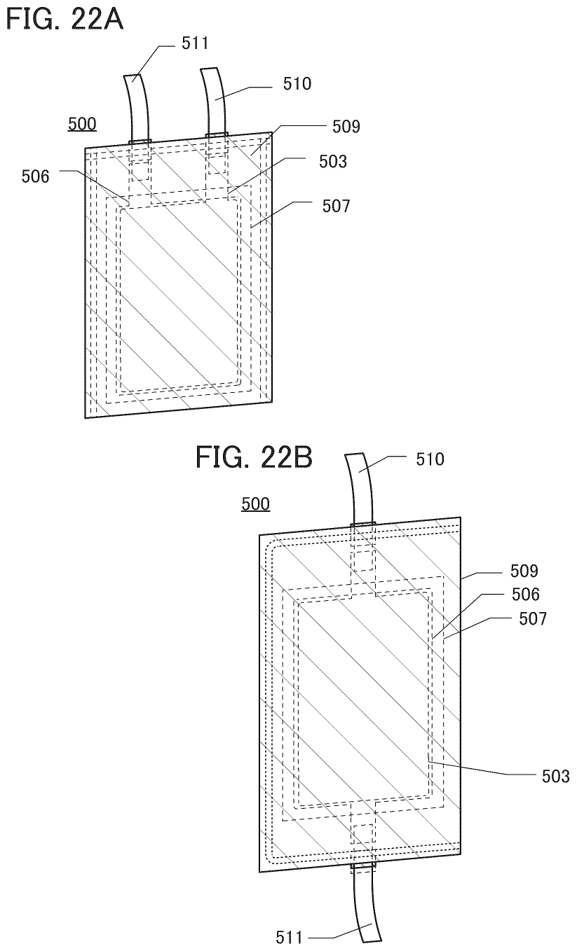

Next, examples of the appearance of a laminated secondary battery are illustrated in FIG. 22A and FIG. 22B. In FIG. 22A and FIG. 22B, a positive electrode 503, a negative electrode 506, a separator 507, an exterior body 509, a positive electrode lead electrode 510, and a negative electrode lead electrode 511 are included. A portion of the positive electrode lead electrode 510 that is exposed to the outside of the secondary battery can be referred to as a positive electrode terminal, and a portion of the negative electrode lead electrode 511 that is exposed to the outside of the secondary battery can be referred to as a negative electrode terminal.

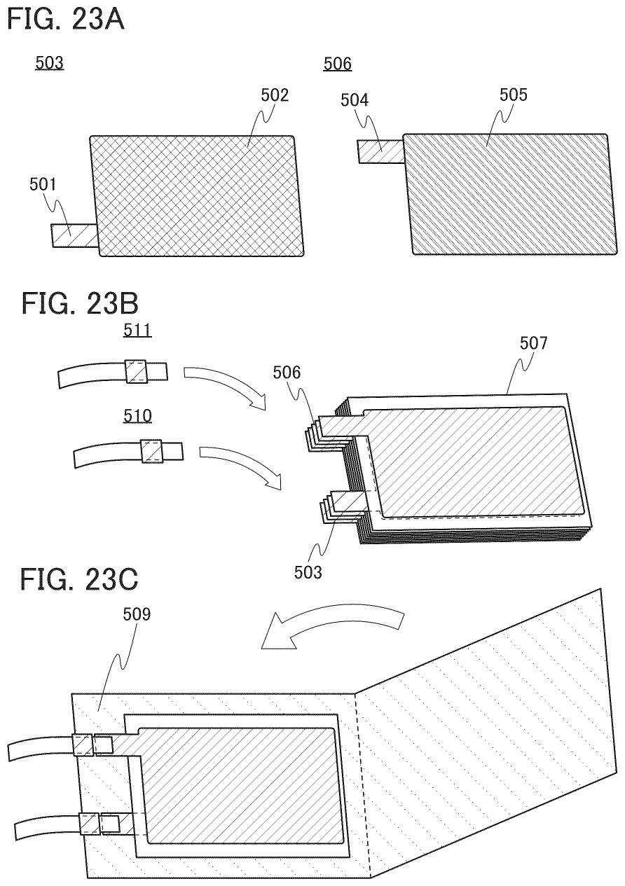

FIG. 23A illustrates the appearance of the positive electrode 503 and the negative electrode 506. The positive electrode 503 includes a positive electrode current collector 501, and a positive electrode active material layer 502 is formed on a surface of the positive electrode current collector 501. The positive electrode 503 also includes a region where the positive electrode current collector 501 is partly exposed (hereinafter referred to as a tab region). The negative electrode 506 includes a negative electrode current collector 504, and a negative electrode active material layer 505 is formed on a surface of the negative electrode current collector 504. The negative electrode 506 also includes a region where the negative electrode current collector 504 is partly exposed, that is, a tab region. The areas or the shapes of the tab regions included in the positive electrode and the negative electrode are not limited to the examples illustrated in FIG. 23A.

### Method for Fabricating Laminated Secondary Battery

An example of a method for fabricating the laminated secondary battery whose external view is illustrated in FIG. 22A will be described with reference to FIG. 23B and FIG. 23C.

First, the negative electrode 506, the separator 507, and the positive electrode 503 are stacked. FIG. 23B illustrates the negative electrodes 506, the separators 507, and the positive electrodes 503 that are stacked. Here, an example in which five negative electrodes and four positive electrodes are used is illustrated. The component can also be referred to as a stack including the negative electrodes, the separators, and the positive electrodes. Next, the tab regions of the positive electrodes 503 are bonded to each other, and the positive electrode lead electrode 510 is bonded to the tab region of the positive electrode on the outermost surface. The bonding is performed by ultrasonic welding, for example. In a similar manner, the tab regions of the negative electrodes 506 are bonded to each other, and the negative electrode lead electrode 511 is bonded to the tab region of the negative electrode on the outermost surface.

After that, the negative electrodes 506, the separators 507, and the positive electrodes 503 are placed over the exterior body 509.

Subsequently, the exterior body 509 is folded along a portion indicated by a dashed line, as illustrated in FIG. 23C. Then, the outer edges of the exterior body 509 are bonded to each other. The bonding is performed by thermocompression bonding, for example. At this time, an unbonded region (hereinafter referred to as an inlet) is provided for part (or one side) of the exterior body 509 so that an electrolyte solution can be introduced later.

Next, the electrolyte solution is introduced into the exterior body 509 from the inlet of the exterior body 509. The electrolyte solution is preferably introduced in a reduced pressure atmosphere or in an inert atmosphere. Lastly, the inlet is bonded. In this manner, the laminated secondary battery 500 can be fabricated.

### Examples of Battery Pack

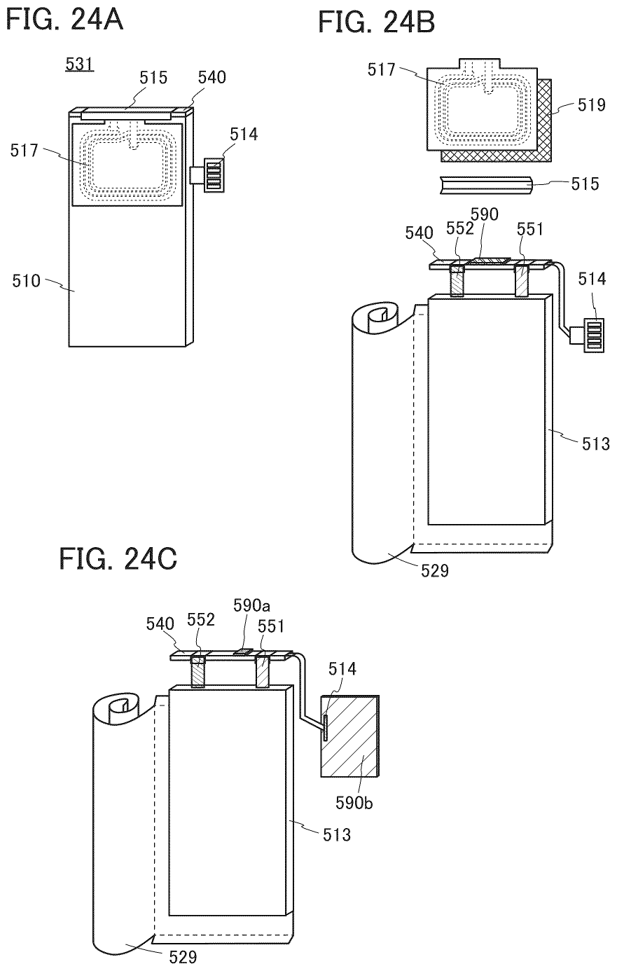

Examples of a secondary battery pack of one embodiment of the present invention that is capable of wireless charging using an antenna will be described with reference to FIG. 24.

FIG. 24A is a diagram illustrating the appearance of a secondary battery pack 531 that has a rectangular solid shape with a small thickness (also referred to as a flat plate shape with a certain thickness). FIG. 24B is a diagram illustrating a structure of the secondary battery pack 531. The secondary battery pack 531 includes a circuit board 540 and a secondary battery 513. A label 529 is attached to the secondary battery 513. The circuit board 540 is fixed by a sealant 515. The secondary battery pack 531 also includes an antenna 517.

A wound body or a stack may be included inside the secondary battery 513.

In the secondary battery pack 531, a control circuit 590 is provided over the circuit board 540 as illustrated in FIG. 24B, for example. The circuit board 540 is electrically connected to a terminal 514. The circuit board 540 is electrically connected to the antenna 517, one 551 of a positive electrode lead and a negative electrode lead of the secondary battery 513, and the other 552 of the positive electrode lead and the negative electrode lead. Note that in some cases, the positive electrode lead is referred to as a positive electrode terminal and the negative electrode lead is referred to as a negative electrode terminal.

In the secondary battery pack 531, the structure of the power storage module 100 or the like described in Embodiment 1 can be used for the structures of the secondary battery 513 and the control circuit 590.

Alternatively, as illustrated in FIG. 24C, a circuit system 590a provided over the circuit board 540 and a circuit system 590b electrically connected to the circuit board 540 through the terminal 514 may be included. Note that the terminal 514 includes a plurality of terminals including at least a high potential terminal (the external terminal 51 in FIG. 1B) and a low potential terminal (the external terminal 52 in FIG. 1B).

Note that the shape of the antenna 517 is not limited to a coil shape and may be a linear shape or a plate shape, for example. An antenna such as a planar antenna, an aperture antenna, a traveling-wave antenna, an EH antenna, a magnetic-field antenna, or a dielectric antenna may be used. Alternatively, the antenna 517 may be a flat-plate conductor. The flat-plate conductor can serve as one of conductors for electric field coupling. That is, the antenna 517 can function as one of two conductors of a capacitor. Thus, electric power can be transmitted and received not only by an electromagnetic field or a magnetic field but also by an electric field.

The secondary battery pack 531 includes a layer 519 between the antenna 517 and the secondary battery 513. The layer 519 has a function of blocking an electromagnetic field from the secondary battery 513, for example. As the layer 519, a magnetic material can be used, for example.

The structure, method, and the like described in this embodiment can be used in an appropriate combination with structures, methods, and the like described in the other embodiments.

### Embodiment 4

In this embodiment, examples of vehicles each including the secondary battery of one embodiment of the present invention will be described. The structure of the power storage module 100 or the like described in Embodiment 1 can be used for the secondary battery and the control circuit described in this embodiment.

The secondary battery can be used in vehicles, typically automobiles. Examples of the automobiles include next-generation clean energy vehicles such as hybrid vehicles (HVs), electric vehicles (EVs), and plug-in hybrid vehicles (PHEVs or PHVs), and the secondary battery can be used as one of the power sources provided for the automobiles. The vehicles are not limited to automobiles. Examples of the vehicles include a train, a monorail train, a ship, a submarine (a deep-submergence vehicle and an unmanned submarine), a flying object (a helicopter, an unmanned aircraft (a drone), an airplane, a rocket, and an artificial satellite), an electric bicycle, and an electric motorcycle, and the secondary battery of one embodiment of the present invention can be used for the vehicles.

The electric vehicle is provided with first power storage devices 1301a and 1301b as main secondary batteries for driving and a second power storage device 1311 that supplies electric power to an inverter 1312 for starting a motor 1304. The second power storage device 1311 is also referred to as a cranking battery (also referred to as a starter battery). The second power storage device 1311 only needs high output and high capacity is not so much needed; the capacity of the second power storage device 1311 is lower than that of the first power storage devices 1301a and 1301b.

The internal structure of the first power storage device 1301a may be the wound structure illustrated in FIG. 20C or FIG. 21A or the stacked-layer structure illustrated in FIG. 22A or FIG. 22B. Alternatively, the all-solid-state battery may be used as the first power storage device 1301a. The use of the all-solid-state battery as the first power storage device 1301a can achieve high capacity, improvement in safety, and reduction in size and weight.

Although this embodiment describes an example in which the two first power storage devices 1301a and 1301b are connected in parallel, three or more power storage devices may be connected in parallel. In the case where the first power storage device 1301a can store sufficient electric power, the first power storage device 1301b may be omitted. A battery pack including a plurality of secondary batteries is formed using the power storage device, whereby large electric power can be extracted. The plurality of secondary batteries may be connected in parallel, connected in series, or connected in series after being connected in parallel. The plurality of secondary batteries are also referred to as an assembled battery.

In order to cut off electric power from the plurality of secondary batteries, the secondary batteries in the vehicle include a service plug or a circuit breaker that can cut off a high voltage without the use of equipment. The first power storage device 1301a is provided with such a service plug or a circuit breaker.

Electric power from the first power storage devices 1301a and 1301b is mainly used to rotate the motor 1304 and is supplied to in-vehicle parts for 42 V (such as an electric power steering 1307, a heater 1308, and a defogger 1309) through a DCDC circuit 1306. Even in the case where there is a rear motor 1317 for rear wheels, the first power storage device 1301a is used to rotate the rear motor 1317.

The second power storage device 1311 supplies electric power to in-vehicle parts for 14 V (such as a stereo 1313, a power window 1314, and lamps 1315) through a DCDC circuit 1310.

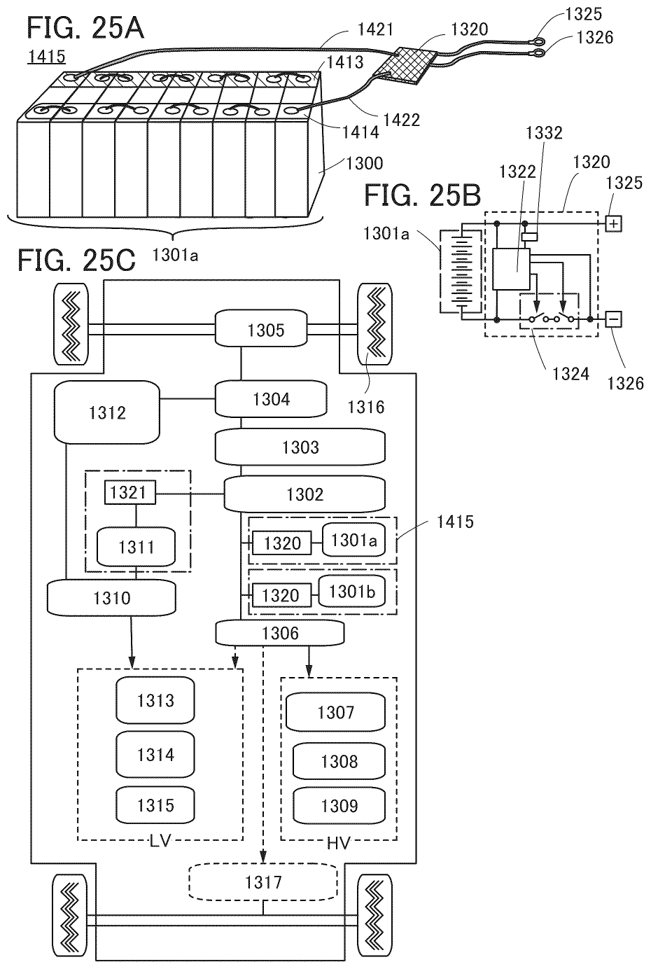

Next, the first power storage device 1301a is described with reference to FIG. 25A.

FIG. 25A illustrates an example in which nine rectangular secondary batteries 1300 form one power storage module 1415. The nine rectangular secondary batteries 1300 are connected in series; one electrode of each battery is fixed by a fixing portion 1413 made of an insulator, and the other electrode thereof is fixed by a fixing portion 1414 made of an insulator. Although this embodiment describes an example in which the secondary batteries are fixed by the fixing portions 1413 and 1414, they may be stored in a battery container box (also referred to as a housing). Since a vibration or a jolt is assumed to be given to the vehicle from the outside (e.g., a road surface), the plurality of secondary batteries are preferably fixed by the fixing portion 1413 or 1414, a battery container box, or the like. Furthermore, the one electrode is electrically connected to a control circuit portion 1320 through a wiring 1421. Furthermore, the other electrode is electrically connected to the control circuit portion 1320 through a wiring 1422. In the first power storage device 1301a, between the electrodes connected to the wiring 1421 and the electrodes connected to the wiring 1422, the electrodes with high potentials can be referred to as a positive electrode terminal of the first power storage device 1301a. and the electrodes with low potentials can be referred to as a negative electrode terminal of the first power storage device 1301a. The control circuit portion 1320 includes an external connection terminal 1325 and an external connection terminal 1326.

The control circuit portion 1320 may include a memory circuit including a transistor using an oxide semiconductor. A charge control circuit or a battery control system that includes a memory circuit including a transistor using an oxide semiconductor is referred to as a BTOS (Battery operating system or Battery oxide semiconductor) in some cases.

A metal oxide functioning as an oxide semiconductor is preferably used. For example, as the metal oxide, a metal oxide such as an In-M-Zn oxide (an element M is one or more kinds selected from aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) or the like is preferably used. In particular, the In-M-Zn oxide that can be used as the metal oxide is preferably a CAAC-OS (C-Axis Aligned Crystal Oxide Semiconductor) or a CAC-OS (Cloud-Aligned Composite Oxide Semiconductor). Alternatively, an In—Ga oxide or an In—Zn oxide may be used as the metal oxide. The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement.

Note that the “CAC-OS” has a composition in which materials are separated into first regions and second regions to form a mosaic pattern, and the first regions are distributed in the film (this composition is hereinafter also referred to as a cloud-like composition). That is, the CAC-OS is a composite metal oxide having a composition in which the first regions and the second regions are mixed. Note that a clear boundary between the first region and the second region is not easily observed in some cases.

For example, energy dispersive X-ray spectroscopy (EDX) is used to obtain EDX mapping, and according to the EDX mapping, the CAC-OS in the In—Ga—Zn oxide can be found to have a structure in which the region containing In as its main component (the first region) and the region containing Ga as its main component (the second region) are unevenly distributed and mixed.

In the case where the CAC-OS is used for a transistor, a switching function (On/Off switching function) can be given to the CAC-OS owing to the complementary action of the conductivity derived from the first region and the insulating property derived from the second region. That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Iₒₙ), a high field-effect mobility (μ), and favorable switching operation can be achieved.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

The control circuit portion 1320 preferably includes a transistor using an oxide semiconductor because it can be used in a high-temperature environment. For the process simplicity, the control circuit portion 1320 may be formed using transistors of the same conductivity type. A transistor using an oxide semiconductor in its semiconductor layer has an operating ambient temperature range of −40° C. to 150° C., which is wider than that of a single crystal Si transistor, and thus shows a smaller change in characteristics than the single crystal Si transistor when the secondary battery is overheated. The off-state current of the transistor using an oxide semiconductor is lower than or equal to the lower measurement limit even at 150° C. independently of the temperature; meanwhile, the off-state current characteristics of the single crystal Si transistor largely depend on the temperature. For example, at 150° C., the off-state current of the single crystal Si transistor increases, and a sufficiently high current on/off ratio cannot be obtained. The control circuit portion 1320 can improve the safety.

The control circuit portion 1320 that includes a memory circuit including a transistor using an oxide semiconductor can also function as an automatic control device for the secondary battery to resolve causes of instability, such as a micro-short circuit. Examples of functions of resolving causes of instability such as a micro-short circuit include prevention of overcharging, prevention of overcurrent, control of overheating during charging, cell balance of an assembled battery, prevention of overdischarging, a battery indicator, automatic control of charge voltage and current amount according to temperature, control of the amount of charge current according to the degree of deterioration, abnormal behavior sensing for a micro-short circuit, and anomaly prediction regarding a micro-short circuit; the control circuit portion 1320 has at least one of these functions. Furthermore, the automatic control device for the secondary battery can be extremely small in size.

A “micro-short circuit” refers to a minute short circuit caused in a secondary battery and refers not to a state where the positive electrode and the negative electrode of a secondary battery are short-circuited so that charging and discharging are impossible, but to a phenomenon in which a slight short-circuit current flows through a minute short-circuit portion. Since a large voltage change is caused even when a micro-short circuit occurs in a relatively short time in a minute area, the abnormal voltage value might adversely affect estimation to be performed subsequently.

One of the causes of a micro-short circuit is as follows: charging and discharging performed a plurality of times cause uneven distribution of positive electrode active materials, which leads to local concentration of current in part of the positive electrode and part of the negative electrode, whereby part of a separator stops functioning or a by-product is generated by a side reaction, which is thought to generate a micro short-circuit.

It can be said that the control circuit portion 1320 not only senses a micro-short circuit but also senses a terminal voltage of the secondary battery and controls the charge and discharge state of the secondary battery. For example, to prevent overcharging, an output transistor of a charge circuit and an interruption switch can be turned off substantially at the same time.

Next, FIG. 25B illustrates an example of a block diagram of the power storage module 1415 illustrated in FIG. 25A.

The control circuit portion 1320 includes a switch portion 1324 that includes at least a switch for preventing overcharging and a switch for preventing overdischarging, a control circuit 1322 for controlling the switch portion 1324, a portion for measuring the voltage of the first power storage device 1301a, and a PTC element 1332. The control circuit portion 1320 is set to have the upper limit voltage and the lower limit voltage of the secondary battery to be used, and imposes the upper limit of current from the outside, the upper limit of output current to the outside, or the like. The range from the lower limit voltage to the upper limit voltage of the secondary battery falls within the recommended voltage range; when a voltage falls outside the range, the switch portion 1324 operates and functions as a protection circuit. The control circuit portion 1320 can also be referred to as a protection circuit because it controls the switch portion 1324 to prevent overdischarging and/or overcharging. For example, when the control circuit 1322 senses a voltage that is likely to cause overcharging, current is interrupted by turning off the switch in the switch portion 1324. Furthermore, a function of interrupting current in accordance with a temperature rise may be set by providing a PTC element in the charge and discharge path. The control circuit portion 1320 includes the external connection terminal 1325 (+IN) and the external connection terminal 1326 (−IN).

The switch portion 1324 can be formed by a combination of an n-channel transistor and a p-channel transistor. The switch portion 1324 is not limited to a switch including a Si transistor using single crystal silicon; the switch portion 1324 may be formed using, for example, a power transistor containing Ge (germanium), SiGe (silicon germanium), GaAs (gallium arsenide), GaAlAs (gallium aluminum arsenide), InP (indium phosphide), SiC (silicon carbide), ZnSe (zinc selenide), GaN (gallium nitride), GaOx (gallium oxide, where x is a real number greater than (), or the like. A memory element using an OS transistor can be freely placed by being stacked over a circuit using a Si transistor, for example; hence, integration can be easy. Furthermore, an OS transistor can be fabricated with a manufacturing apparatus similar to that for a Si transistor and thus can be fabricated at low cost. That is, the control circuit portion 1320 using an OS transistor can be stacked over the switch portion 1324 so that they can be integrated into one chip. Since the volume occupied by the control circuit portion 1320 can be reduced, a reduction in size is possible.

The first power storage devices 1301a and 1301b mainly supply electric power to in-vehicle parts for 42 V (high-voltage systems HV), and the second power storage device 1311 supplies electric power to in-vehicle parts for 14 V (low-voltage systems LV). Lead storage batteries are usually used for the second power storage device 1311 due to cost advantage. Lead storage batteries have disadvantages compared with lithium-ion batteries in that they have a larger amount of self-discharging and are more likely to deteriorate due to a phenomenon called sulfation. There is an advantage that the second power storage device 1311 can be maintenance-free when a lithium-ion battery is used; however, in the case of long-term use, for example three years or more, anomaly that is difficult to determine at the time of manufacturing might occur. In particular, when the second power storage device 1311 that starts the inverter becomes inoperative, the motor cannot be started even when the first power storage devices 1301a and 1301b have remaining capacity; thus, in order to prevent this, in the case where the second power storage device 1311 is a lead storage battery, the second battery is supplied with electric power from the first battery to constantly maintain a fully-charged state.

In this embodiment, an example in which a lithium-ion battery is used as both the first power storage device 1301a and the second power storage device 1311 is described (FIG. 23C). As the second power storage device 1311, a lead storage battery, an all-solid-state battery, or an electric double layer capacitor may be used. For example, the all-solid-state battery may be used. The use of the all-solid-state battery as the second power storage device 1311 can achieve high capacity and reduction in size and weight.

Regenerative energy generated by rolling of tires 1316 is transmitted to the motor 1304 through a gear 1305, and is stored in the second power storage device 1311 from a motor controller 1303 and a battery controller 1302 through a control circuit portion 1321. Alternatively, the regenerative energy is stored in the first power storage device 1301a from the battery controller 1302 through the control circuit portion 1320. Alternatively, the regenerative energy is stored in the first power storage device 1301b from the battery controller 1302 through the control circuit portion 1320. For efficient charging with regenerative energy, the first power storage devices 1301a and 1301b are desirably capable of fast charging.

The battery controller 1302 can set the charge voltage, charge current, and the like of the first power storage devices 1301a and 1301b. The battery controller 1302 can set charge conditions in accordance with charge performance of a secondary battery used, so that fast charging can be performed.

Although not illustrated, in the case of connecting an electric vehicle to an external charger, a plug of the charger or a connection cable of the charger is electrically connected to the battery controller 1302. Electric power supplied from the external charger is stored in the first power storage devices 1301a and 1301b through the battery controller 1302. Some chargers are provided with a control circuit, in which case the function of the battery controller 1302 is not used; to prevent overcharging, the first power storage devices 1301a and 1301b are preferably charged through the control circuit portion 1320. In addition, the plug of the charger or the connection cable of the charger is sometimes provided with a control circuit. The control circuit portion 1320 is also referred to as an ECU (Electronic Control Unit). The ECU is connected to a CAN (Controller Area Network) provided in the electric motor vehicle. The CAN is a type of a serial communication standard used as an in-vehicle LAN. The ECU includes a microcomputer. Moreover, the ECU uses a CPU or a GPU.

External chargers installed at charging stations and the like have a 100 V outlet, a 200 V outlet, or a three-phase 200 V outlet with 50 kW, for example. Furthermore, charging can be performed with electric power supplied from external charging equipment by a contactless power feeding method or the like.

For fast charging, secondary batteries that can withstand high-voltage charging have been desired to perform charging in a short time.

Moreover, it is possible to achieve a secondary battery in which graphene is used as a conductive material, an electrode layer is formed thick to increase the loading amount while suppressing a reduction in capacity, and the electrical characteristics are significantly improved in synergy with maintenance of high capacity. This secondary battery is particularly effectively used in a vehicle; it is possible to provide a vehicle that has a long cruising range, specifically one charge mileage of 500 km or greater, without increasing the proportion of the weight of the secondary battery to the weight of the entire vehicle.

Next, examples in which the secondary battery of one embodiment of the present invention is mounted on a vehicle, typically a transport vehicle, will be described.

Mounting the secondary battery illustrated in any of FIG. 19D, FIG. 21C, and FIG. 25A on vehicles can achieve next-generation clean energy vehicles such as hybrid vehicles (HVs), electric vehicles (EVs), and plug-in hybrid vehicles (PHVs). The secondary battery can also be mounted on agricultural machines, motorized bicycles including motor-assisted bicycles, motorcycles, electric wheelchairs, electric carts, boats and ships, submarines, aircraft, rockets, artificial satellites, space probes, planetary probes, or spacecraft. The secondary battery of one embodiment of the present invention can be a secondary battery with high capacity. Thus, the secondary battery of one embodiment of the present invention is suitable for reduction in size and reduction in weight and is preferably used in transport vehicles.

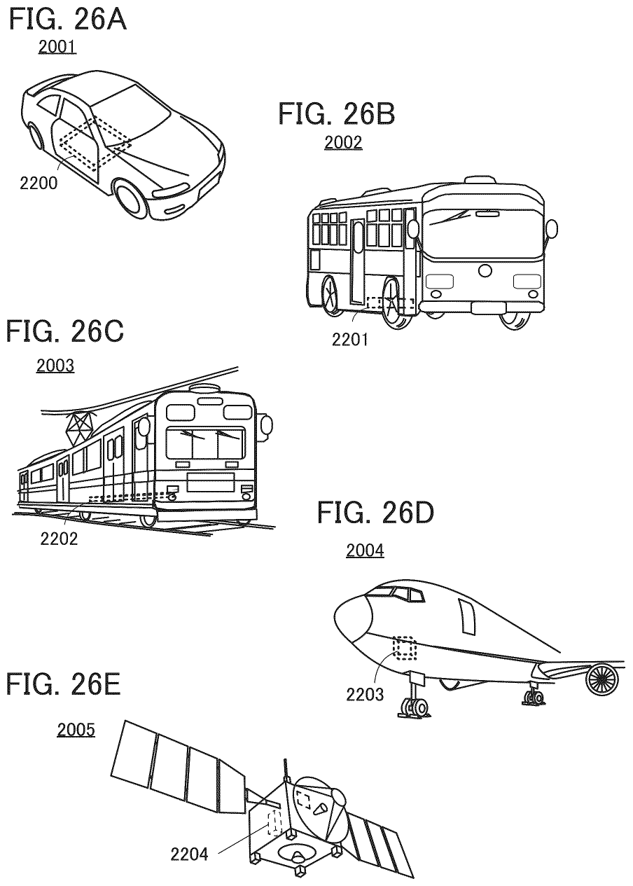

FIG. 26A to FIG. 26D illustrate examples of transport vehicles using one embodiment of the present invention. An automobile 2001 illustrated in FIG. 26A is an electric vehicle that runs using an electric motor as a driving power source. Alternatively, the automobile 2001 is a hybrid vehicle that enables appropriate selection of an electric motor or an engine as a driving power source. In the case where the secondary battery is mounted on the vehicle, an example of the secondary battery described in Embodiment 3 is provided at one position or several positions. The automobile 2001 illustrated in FIG. 26A includes a battery pack 2200, and the battery pack includes a power storage module in which a plurality of secondary batteries are connected to each other. Moreover, the battery pack preferably includes a charge control device that is electrically connected to the power storage module.

The automobile 2001 can be charged when the secondary battery included in the automobile 2001 is supplied with electric power from external charging equipment by a plug-in system, a contactless charge system, or the like. In charging, a given method such as CHAdeMO (registered trademark) or Combined Charging System may be employed as a charge method, the standard of a connector, or the like as appropriate. Charging equipment may be a charge station provided in a commerce facility or a household power supply. For example, with the use of a plug-in technique, the power storage device mounted on the automobile 2001 can be charged by being supplied with electric power from the outside. Charging can be performed by converting AC power into DC power through a converter such as an ACDC converter.

Although not illustrated, the vehicle may be provided with a power receiving device so that it can be charged by being supplied with electric power from an above-ground power transmitting device in a contactless manner. In the case of the contactless power feeding system, by fitting a power transmitting device in a road or an exterior wall, charging can be performed not only when the vehicle is stopped but also when moving. In addition, the contactless power feeding system may be utilized to perform transmission and reception of electric power between two vehicles. Furthermore, a solar cell may be provided in the exterior of the vehicle to charge the secondary battery while the vehicle is stopped or while the vehicle is moving. To supply electric power in such a contactless manner, an electromagnetic induction method or a magnetic resonance method can be used.

FIG. 26B illustrates a large transporter 2002 having a motor controlled by electricity, as an example of a transport vehicle. In a power storage module of the transporter 2002, four secondary batteries each having a nominal voltage of 3.0 V or higher and 5.0 V or lower are used as a cell unit, and 48 cells are connected in series to have a maximum voltage of 170 V, for example. A battery pack 2201 has the same function as that in FIG. 26A except, for example, the number of secondary batteries configuring the power storage module; thus, the description is omitted.

FIG. 26C illustrates a large transport vehicle 2003 having a motor controlled by electricity as an example. In a power storage module of the transport vehicle 2003, 100 or more secondary batteries each having a nominal voltage of 3.0 V or higher and 5.0 V or lower are connected in series to have a maximum voltage of 600 V, for example. Thus, the secondary batteries are required to have a small variation in the characteristics.

FIG. 26D illustrates an aircraft 2004 having a combustion engine as an example. The aircraft 2004 illustrated in FIG. 26D can also be regarded as a kind of transport vehicle because it has wheels for takeoff and landing, and includes a battery pack 2203 that includes a charge control device and a power storage module configured by connecting a plurality of secondary batteries.

The power storage module of the aircraft 2004 has eight 4 V secondary batteries connected in series, which has a maximum voltage of 32 V, for example. The battery pack 2203 has the same function as that in FIG. 26A except, for example, the number of secondary batteries configuring the power storage module; thus, the description is omitted.

FIG. 26E illustrates an artificial satellite 2005 including a secondary battery 2204 as an example. Because the artificial satellite 2005 is used in an ultra-low-temperature cosmic space, the secondary battery 2204 having excellent low temperature resistance of one embodiment of the present invention is preferably provided. It is further preferable that the secondary battery 2204 be mounted inside the artificial satellite 2005 while being covered with a heat-retaining member.

The structure, method, and the like described in this embodiment can be used in an appropriate combination with structures, methods, and the like described in the other embodiments.

### Embodiment 5

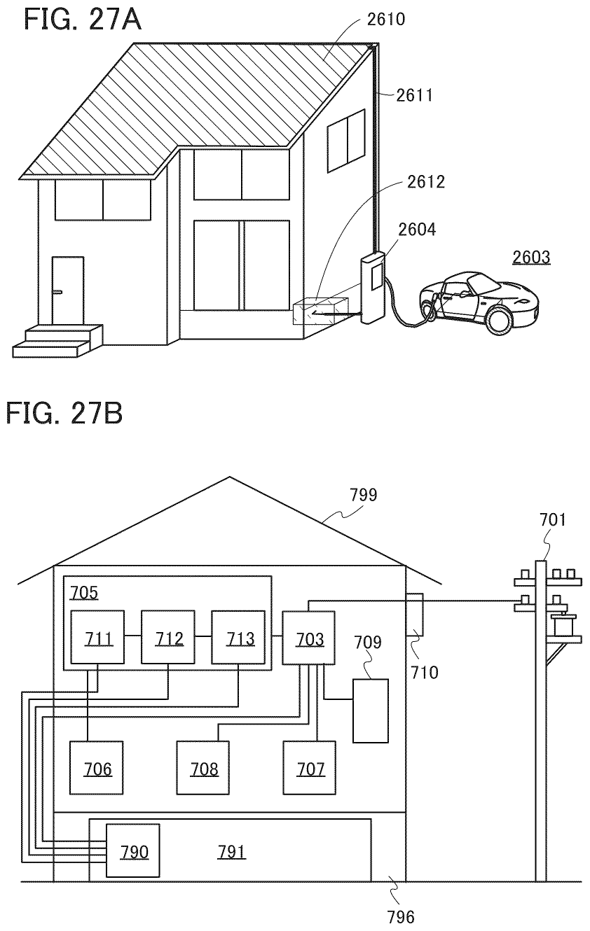

In this embodiment, examples in which the secondary battery of one embodiment of the present invention is mounted on a building will be described with reference to FIG. 27A and FIG. 27B. The structure of the power storage module 100 or the like described in Embodiment 1 can be used for the secondary battery and the control circuit described in this embodiment.

A house illustrated in FIG. 27A includes a power storage device 2612 including the secondary battery of one embodiment of the present invention and a solar panel 2610. The power storage device 2612 is electrically connected to the solar panel 2610 through a wiring 2611 or the like. The power storage device 2612 may be electrically connected to a ground-based charge apparatus 2604. The power storage device 2612 can be charged with electric power generated by the solar panel 2610. A secondary battery included in a vehicle 2603 can be charged with the electric power stored in the power storage device 2612 through the charge apparatus 2604. The power storage device 2612 is preferably provided in an underfloor space. When the power storage device 2612 is provided in the underfloor space, the space on the floor can be effectively used. Alternatively, the power storage device 2612 may be provided on the floor.

The electric power stored in the power storage device 2612 can also be supplied to other electronic devices in the house. Thus, with use of the power storage device 2612 of one embodiment of the present invention as an uninterruptible power source, electronic devices can be used even when electric power cannot be supplied from a commercial power source due to power failure or the like.

FIG. 27B illustrates an example of a power storage device of one embodiment of the present invention. As illustrated in FIG. 27B, a power storage device 791 of one embodiment of the present invention is provided in an underfloor space 796 of a building 799.

The power storage device 791 is provided with a control device 790, and the control device 790 is electrically connected to a distribution board 703, a power storage controller 705 (also referred to as a control device), an indicator 706, and a router 709 through wirings.

Electric power is transmitted from a commercial power source 701 to the distribution board 703 through a service wire mounting portion 710. Moreover, electric power is transmitted to the distribution board 703 from the power storage device 791 and the commercial power source 701, and the distribution board 703 supplies the transmitted electric power to a general load 707 and a power storage load 708 through outlets (not illustrated).

The general load 707 is, for example, an electric device such as a TV or a personal computer. The power storage load 708 is, for example, an electric device such as a microwave oven, a refrigerator, or an air conditioner.

The power storage controller 705 includes a measuring portion 711, a predicting portion 712, and a planning portion 713. The measuring portion 711 has a function of measuring the amount of electric power consumed by the general load 707 and the power storage load 708 during a day (e.g., from midnight to midnight). The measuring portion 711 may have a function of measuring the amount of electric power of the power storage device 791 and the amount of electric power supplied from the commercial power source 701. The predicting portion 712 has a function of predicting, on the basis of the amount of electric power consumed by the general load 707 and the power storage load 708 during a given day, the demand for electric power consumed by the general load 707 and the power storage load 708 during the next day. The planning portion 713 has a function of making a charge and discharge plan of the power storage device 791 on the basis of the demand for electric power predicted by the predicting portion 712.

The amount of electric power consumed by the general load 707 and the power storage load 708 and measured by the measuring portion 711 can be checked with the indicator 706. It can also be checked with an electric device such as a TV or a personal computer through the router 709. Furthermore, it can be checked with a portable electronic terminal such as a smartphone or a tablet through the router 709. With the indicator 706, the electric device, or the portable electronic terminal, the demand for electric power in every time period (or per hour) that is predicted by the predicting portion 712 can be checked.

The structure, method, and the like described in this embodiment can be used in an appropriate combination with structures, methods, and the like described in the other embodiments.

### Embodiment 6

This embodiment describes examples in which the lithium-ion battery of one embodiment of the present invention is mounted on a two-wheeled vehicle and a bicycle as examples of mounting a secondary battery on a vehicle. The structure of the power storage module 100 or the like described in Embodiment 1 can be used for the secondary battery and the control circuit described in this embodiment.

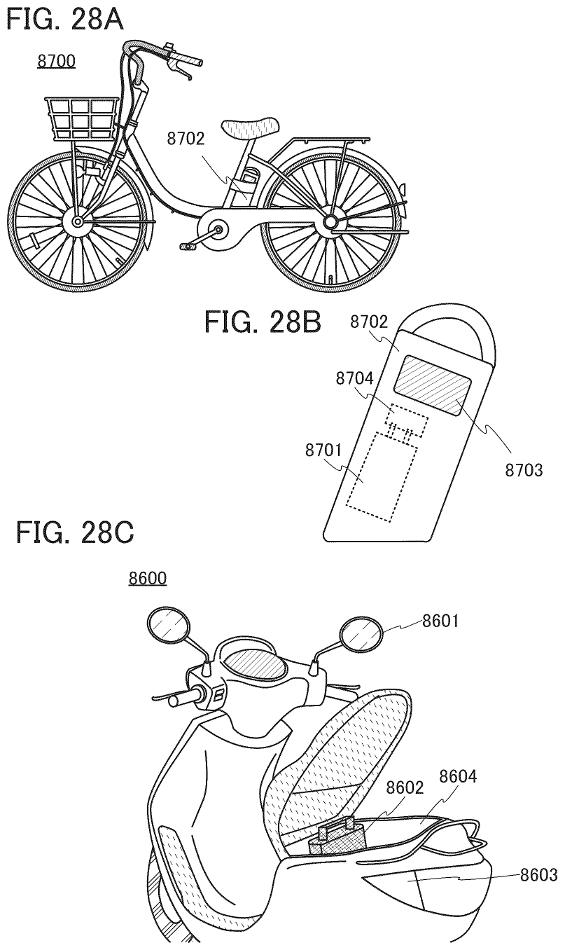

FIG. 28A illustrates an example of an electric bicycle using the power storage device of one embodiment of the present invention. The power storage device of one embodiment of the present invention can be used for an electric bicycle 8700 illustrated in FIG. 28A. The power storage device of one embodiment of the present invention includes a plurality of storage batteries and a protection circuit, for example.

The electric bicycle 8700 includes a power storage device 8702. The power storage device 8702 can supply electricity to a motor that assists a rider. The power storage device 8702 is portable, and FIG. 28B illustrates the state where the power storage device 8702 is detached from the bicycle. A plurality of storage batteries 8701 included in the power storage device of one embodiment of the present invention are incorporated in the power storage device 8702, and the remaining battery capacity and the like can be displayed on a display portion 8703. The power storage device 8702 includes a control circuit 8704 capable of charge control or anomaly sensing for the secondary battery, which is exemplified in Embodiment 6. The control circuit 8704 is electrically connected to a positive electrode and a negative electrode of the storage battery 8701.

FIG. 28C illustrates an example of a two-wheeled vehicle including the power storage device of one embodiment of the present invention. A motor scooter 8600 illustrated in FIG. 28C includes a power storage device 8602, side mirrors 8601, and indicator lights 8603. The power storage device 8602 can supply electricity to the indicator lights 8603.

In the motor scooter 8600 illustrated in FIG. 28C, the power storage device 8602 can be stored in an under-seat storage unit 8604. The power storage device 8602 can be stored in the under-seat storage unit 8604 even when the under-seat storage unit 8604 is small.

The structure, method, and the like described in this embodiment can be used in an appropriate combination with structures, methods, and the like described in the other embodiments.

### Embodiment 7

In this embodiment, examples of electronic devices each including the secondary battery of one embodiment of the present invention will be described. Examples of electronic devices including the secondary battery include a television device (also referred to as a television or a television receiver), a monitor of a computer and the like, a digital camera, a digital video camera, a digital photo frame, a mobile phone (also referred to as a cellular phone or a mobile phone device), a portable game machine, a portable information terminal, an audio reproducing device, and a large-sized game machine such as a pachinko machine. Examples of the portable information terminal include a laptop personal computer, a tablet terminal, an e-book reader, and a mobile phone. The structure of the power storage module 100 or the like described in Embodiment 1 can be used for the secondary battery and the control circuit described in this embodiment.

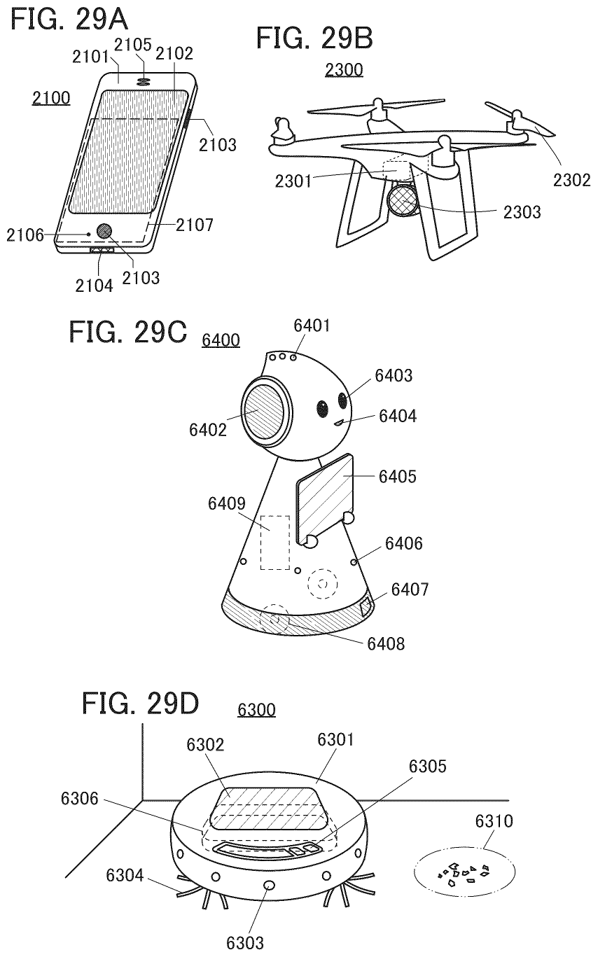

FIG. 29A illustrates an example of a mobile phone. A mobile phone 2100 includes a display portion 2102 set in a housing 2101, operation buttons 2103, an external connection port 2104, a speaker 2105, a microphone 2106, and the like. The mobile phone 2100 includes a secondary battery 2107.

The mobile phone 2100 is capable of executing a variety of applications such as mobile phone calls, e-mailing, text viewing and editing, music reproduction, Internet communication, and a computer game.

With the operation buttons 2103, a variety of functions such as time setting, power on/off, on/off of wireless communication, setting and cancellation of a silent mode, and setting and cancellation of a power saving mode can be performed. For example, the functions of the operation buttons 2103 can be set freely by an operating system incorporated in the mobile phone 2100.

The mobile phone 2100 can execute near field communication conformable to a communication standard. For example, mutual communication between the mobile phone 2100 and a headset capable of wireless communication enables hands-free calling.

The mobile phone 2100 includes the external connection port 2104, and can perform direct data transmission and reception with another information terminal via a connector. In addition, charging can be performed via the external connection port 2104. Note that the charging operation may be performed by wireless power feeding without using the external connection port 2104.

The mobile phone 2100 preferably includes a sensor. As the sensor, a human body sensor such as a fingerprint sensor, a pulse sensor, or a temperature sensor, a touch sensor, a pressure sensitive sensor, or an acceleration sensor is preferably mounted, for example.

FIG. 29B illustrates an unmanned aircraft 2300 including a plurality of rotors 2302. The unmanned aircraft 2300 is sometimes also referred to as a drone. The unmanned aircraft 2300 includes a secondary battery 2301 of one embodiment of the present invention, a camera 2303, and an antenna (not illustrated). The unmanned aircraft 2300 can be remotely controlled through the antenna.

FIG. 29C illustrates an example of a robot. A robot 6400 illustrated in FIG. 29C includes a secondary battery 6409, an illuminance sensor 6401, a microphone 6402, an upper camera 6403, a speaker 6404, a display portion 6405, a lower camera 6406, an obstacle sensor 6407, a moving mechanism 6408, an arithmetic device, and the like.

The microphone 6402 has a function of sensing a speaking voice of a user, an environmental sound, and the like. The speaker 6404 has a function of outputting sound. The robot 6400 can communicate with the user using the microphone 6402 and the speaker 6404.

The display portion 6405 has a function of displaying various kinds of information. The robot 6400 can display information desired by the user on the display portion 6405. The display portion 6405 may be provided with a touch panel. Moreover, the display portion 6405 may be a detachable information terminal, in which case charging and data communication can be performed when the display portion 6405 is set at the home position of the robot 6400.

The upper camera 6403 and the lower camera 6406 each have a function of taking an image of the surroundings of the robot 6400. The obstacle sensor 6407 can sense the presence of an obstacle in the direction where the robot 6400 advances with the moving mechanism 6408. The robot 6400 can move safely by recognizing the surroundings with the upper camera 6403, the lower camera 6406, and the obstacle sensor 6407.

The robot 6400 includes, in its inner region, the secondary battery 6409 of one embodiment of the present invention and a semiconductor device or an electronic component.

FIG. 29D illustrates an example of a cleaning robot. A cleaning robot 6300 includes a display portion 6302 placed on a top surface of a housing 6301, a plurality of cameras 6303 placed on a side surface of the housing 6301, a brush 6304, operation buttons 6305, a secondary battery 6306, a variety of sensors, and the like. Although not illustrated, the cleaning robot 6300 is provided with a tire, an inlet, and the like. The cleaning robot 6300 is self-propelled, senses dust 6310, and sucks up the dust through the inlet provided on a bottom surface.

The cleaning robot 6300 can determine whether there is an obstacle such as a wall, furniture, or a step by analyzing images taken by the cameras 6303. In the case where the cleaning robot 6300 senses an object, such as a wire, that is likely to be caught in the brush 6304 by image analysis, the rotation of the brush 6304 can be stopped. The cleaning robot 6300 includes, in its inner region, the secondary battery 6306 according to one embodiment of the present invention and a semiconductor device or an electronic component.

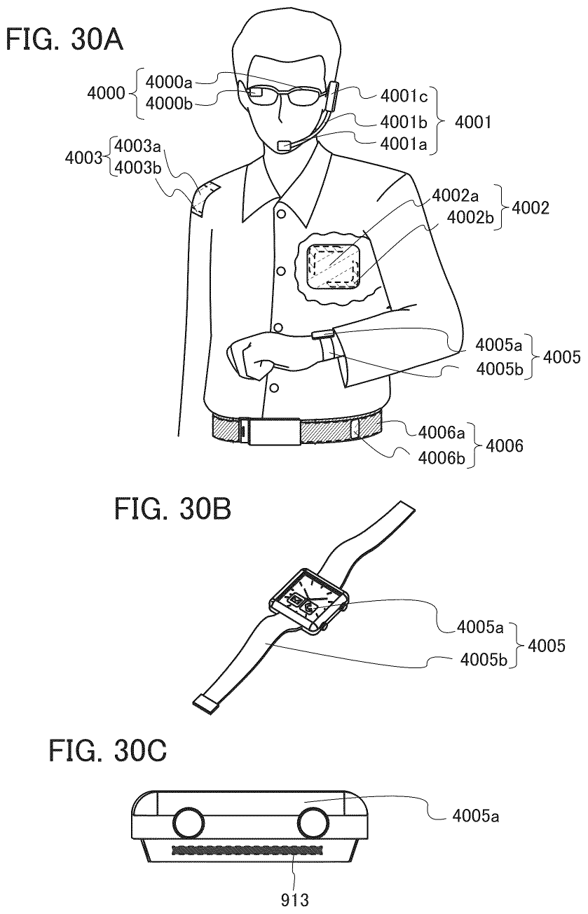

FIG. 30A illustrates examples of wearable devices. A secondary battery is used as a power source of a wearable device. To have improved splash resistance, water resistance, or dust resistance in daily use or outdoor use by a user, a wearable device is desirably capable of being charged with and without a wire whose connector portion for connection is exposed.

For example, the secondary battery of one embodiment of the present invention can be mounted in a glasses-type device 4000 illustrated in FIG. 30A. The glasses-type device 4000 includes a frame 4000a and a display portion 4000b. The secondary battery is mounted in a temple portion of the frame 4000a having a curved shape, whereby the glasses-type device 4000 can be lightweight, can have a well-balanced weight, and can be used continuously for a long time.

The secondary battery of one embodiment of the present invention can be mounted in a headset-type device 4001. The headset-type device 4001 includes at least a microphone portion 4001a, a flexible pipe 4001b, and an earphone portion 4001c. The secondary battery can be provided in the flexible pipe 4001b or the earphone portion 4001c.

The secondary battery of one embodiment of the present invention can be mounted in a device 4002 that can be attached directly to a body. A secondary battery 4002b can be provided in a thin housing 4002a of the device 4002.

The secondary battery of one embodiment of the present invention can be mounted in a device 4003 that can be attached to clothes. A secondary battery 4003b can be provided in a thin housing 4003a of the device 4003.

The secondary battery of one embodiment of the present invention can be mounted in a belt-type device 4006. The belt-type device 4006 includes a belt portion 4006a and a wireless power feeding and receiving portion 4006b, and the secondary battery can be mounted in the inner region of the belt portion 4006a.

The secondary battery of one embodiment of the present invention can be mounted in a watch-type device 4005. The watch-type device 4005 includes a display portion 4005a and a belt portion 4005b, and the secondary battery can be provided in the display portion 4005a or the belt portion 4005b.

The display portion 4005a can display various kinds of information such as time and reception information of an e-mail and an incoming call.

The watch-type device 4005 is a wearable device that is wound around an arm directly; thus, a sensor that measures the pulse, the blood pressure, or the like of the user may be mounted therein. Data on the exercise quantity and health of the user can be stored to be used for health maintenance.

FIG. 30B illustrates a perspective view of the watch-type device 4005 that is detached from an arm.

FIG. 30C illustrates a side view. FIG. 30C illustrates a state where a secondary battery 913 is incorporated in the inner region. The secondary battery 913 is the secondary battery described in Embodiment 3. The secondary battery 913 is provided at a position overlapping with the display portion 4005a, can have high density and high capacity, and is small and lightweight.

The structure, method, and the like described in this embodiment can be used in an appropriate combination with structures, methods, and the like described in the other embodiments.

### Reference Numerals

10A: battery, 10B: battery, 10: battery, 11: battery, 15: control circuit, 21: heater, 22: temperature sensor, 30: circuit board, 31: IC, 33: FET, 34: current sensing element, 35A: TCO element, 35B: TCO element, 35: TCO element, 36: FET, 37: FET, 39: PTC element, 40: FET, 41: resistor, 51: external terminal, 52: external terminal, 53: communication terminal, 54: communication terminal, 61: terminal, 62: terminal, 63: bimetal, 64: exterior body, 65: PTC portion, 100B: power storage module, 100C: power storage module, 100D: power storage module, 100E: power storage module, 100F: power storage module, 100G: power storage module, 100H: power storage module, 100: power storage module, 202A: transistor, 202B: transistor, 203A: diode, 203B: diode, 204A: terminal, 204B: terminal, 205A: terminal, 205B: terminal, 206A: terminal, 206B: terminal, 300: secondary battery, 301: positive electrode can, 302: negative electrode can, 303: gasket, 304: positive electrode, 305: positive electrode current collector, 306: positive electrode active material layer, 307: negative electrode, 308: negative electrode current collector, 309: negative electrode active material layer, 310: separator, 312: washer, 322: spacer, 500: secondary battery, 501: positive electrode current collector, 502: positive electrode active material layer, 503: positive electrode, 504: negative electrode current collector, 505: negative electrode active material layer, 506: negative electrode, 507: separator, 509: exterior body, 510: positive electrode lead electrode, 511: negative electrode lead electrode, 513: secondary battery, 514: terminal, 515: sealant, 517: antenna, 519: layer, 529: label, 531: secondary battery pack, 540: circuit board, 552: other, 590a: circuit system, 590b: circuit system, 590: control circuit, 601: positive electrode cap, 602: battery can, 603: positive electrode terminal, 604: positive electrode, 605: separator, 606: negative electrode, 607: negative electrode terminal, 608: insulating plate, 609: insulating plate, 611: PTC element, 613: safety valve mechanism, 614A: conductive plate, 614B: conductive plate, 614: conductive plate, 615: power storage module, 616: secondary battery, 620: control circuit, 621: wiring, 622: wiring, 623: wiring, 624: conductor, 625: conductor, 626: wiring, 627: wiring, 628A: conductive plate, 628B: conductive plate, 628: conductive plate, 629: external terminal, 630: external terminal, 701: commercial power source, 703: distribution board, 705: power storage controller, 706: indicator, 707: general load, 708: power storage load, 709: router, 710: service wire mounting portion, 711: measuring portion, 712: predicting portion, 713: planning portion, 790: control device, 791: power storage device, 796: underfloor space, 799: building, 911a: terminal, 911b: terminal, 913: secondary battery, 930a: housing, 930b: housing, 930: housing, 931a: negative electrode active material layer, 931: negative electrode, 932a: positive electrode active material layer, 932: positive electrode, 933: separator, 950a: wound body, 950: wound body, 951: terminal, 952: terminal, 1300: rectangular secondary battery, 1301a: first power storage device, 1301b: first power storage device, 1302: battery controller, 1303: motor controller, 1304: motor, 1305: gear, 1306: DCDC circuit, 1307: electric power steering, 1308: heater, 1309: defogger, 1310: DCDC circuit, 1311: second power storage device, 1312: inverter, 1313: stereo, 1314: power window, 1315: lamps, 1316: tire, 1317: rear motor, 1320: control circuit portion, 1321: control circuit portion, 1322: control circuit, 1324: switch portion, 1325: external connection terminal, 1326: external connection terminal, 1332: PTC element, 1413: fixing portion, 1414: fixing portion, 1415: power storage module, 1421: wiring, 1422: wiring, 2001: automobile, 2002: transporter, 2003: transport vehicle, 2004: aircraft, 2005: artificial satellite, 2100: mobile phone, 2101: housing, 2102: display portion, 2103: operation button, 2104: external connection port, 2105: speaker, 2106: microphone, 2107: secondary battery, 2200: battery pack, 2201: battery pack, 2203: battery pack, 2204: secondary battery, 2300: unmanned aircraft, 2301: secondary battery, 2302: rotor, 2303: camera, 2603: vehicle, 2604: charge apparatus, 2610: solar panel, 2611: wiring, 2612: power storage device, 4000a: frame, 4000b: display portion, 4000: glasses-type device, 4001a: microphone portion, 4001b: flexible pipe, 4001c: earphone portion, 4001: headset-type device, 4002a: housing, 4002b: secondary battery, 4002: device, 4003a: housing, 4003b: secondary battery, 4003: device, 4005a: display portion, 4005b: belt portion, 4005: watch-type device, 4006a: belt portion, 4006b: wireless power feeding and receiving portion, 4006: belt-type device, 6300: cleaning robot, 6301: housing, 6302: display portion, 6303: camera, 6304: brush, 6305: operation button, 6306: secondary battery, 6310: dust, 6400: robot, 6401: illuminance sensor, 6402: microphone, 6403: upper camera, 6404: speaker, 6405: display portion, 6406: lower camera, 6407: obstacle sensor, 6408: moving mechanism, 6409: secondary battery, 8600: motor scooter, 8601: side mirror, 8602: power storage device, 8603: indicator light, 8604: under-seat storage unit, 8700: electric bicycle, 8701: storage battery, 8702: power storage device, 8703: display portion, 8704: control circuit

1. A power storage module comprising:
a first battery, a second battery, a heater, and a control circuit,
wherein the first battery and the second battery are connected in series,
wherein the heater is provided close to the first battery and the second battery,
wherein the heater is electrically connected to an IC included in the control circuit,
wherein the control circuit comprises a first voltage sensor that senses a voltage of the first battery, a second voltage sensor that senses a voltage of the second battery, and a current sensor that senses a current flowing through the first battery and the second battery, and
wherein in charging the first battery and the second battery, the heater is turned on by a signal from the IC in the case where a differential voltage between a first peak voltage of dQ/dV calculated from a detection value of each of the first voltage sensor and the current sensor and a second peak voltage of dQ/dV calculated from a detection value of each of the second voltage sensor and the current sensor is higher than or equal to 5 mV.

2. The power storage module according to claim 1, further comprising a temperature sensor,
wherein the temperature sensor is electrically connected to the IC,
wherein the temperature sensor is provided close to the first battery or the second battery, and
wherein after the heater is turned on, the heater is turned off by a signal from the IC in the case where a detection temperature of the temperature sensor is higher than or equal to 25° C.

3. The power storage module according to claim 1, further comprising a temperature sensor,
wherein the temperature sensor is electrically connected to the IC,
wherein the temperature sensor is provided close to the first battery or the second battery, and
wherein in the case where the heater is turned on by the signal from the IC and a first detection temperature is determined as a detection temperature of the temperature sensor immediately before the heater is turned on, the heater is turned off by a signal from the IC when a detection temperature of the temperature sensor is a temperature that is 5° C. higher than the first detection temperature.

4. The power storage module according to claim 1,
wherein after the heater is turned on, the heater is turned off by a signal from the IC in the case where a certain period of time elapses.

5. The power storage module according to claim 2,
wherein in charging the first battery and the second battery, the heater is turned on by the signal from the IC in the case where the detection temperature of the temperature sensor is lower than 10° C., and
wherein the heater is turned off by the signal from the IC when the detection temperature of the temperature sensor is higher than or equal to 25° C.

6. A power storage module comprising:
a first battery, a second battery, a heater, and a control circuit,
wherein the first battery and the second battery are connected,
wherein the heater is provided at a position where the heather is capable of heating the first battery and the second battery,
wherein the heater is electrically connected to an IC included in the control circuit,
wherein the control circuit comprises a first voltage sensor that senses a voltage of the first battery, a second voltage sensor that senses a voltage of the second battery, and a current sensor that senses a current flowing through the first battery and the second battery, and
wherein in charging the first battery and the second battery, the heater is turned on by a signal from the IC in the case where a differential voltage between a first peak voltage of dQ/dV calculated from a detection value of each of the first voltage sensor and the current sensor and a second peak voltage of dQ/dV calculated from a detection value of each of the second voltage sensor and the current sensor is higher than or equal to 5 mV.

7. The power storage module according to claim 6, further comprising a temperature sensor,
wherein the temperature sensor is electrically connected to the IC,
wherein the temperature sensor is provided close to the first battery or the second battery, and
wherein after the heater is turned on, the heater is turned off by a signal from the IC in the case where a detection temperature of the temperature sensor is higher than or equal to 25° C.

8. The power storage module according to claim 6, further comprising a temperature sensor,
wherein the temperature sensor is electrically connected to the IC,
wherein the temperature sensor is provided close to the first battery or the second battery, and
wherein in the case where the heater is turned on by the signal from the IC and a first detection temperature is determined as a detection temperature of the temperature sensor immediately before the heater is turned on, the heater is turned off by a signal from the IC when a detection temperature of the temperature sensor is a temperature that is 5° C. higher than the first detection temperature.

9. The power storage module according to claim 1,
wherein after the heater is turned on, the heater is turned off by a signal from the IC in the case where a certain period of time elapses.

10. The power storage module according to claim 7,
wherein in charging the first battery and the second battery, the heater is turned on by the signal from the IC in the case where the detection temperature of the temperature sensor is lower than 10° C., and
wherein the heater is turned off by the signal from the IC when the detection temperature of the temperature sensor is higher than or equal to 25° C.
